(19) United States
(12) Patent Application Publication
(10) Pub. No.: US 2026/0143742 A1
(43) Pub. Date: May 21, 2026

(54) SEMICONDUCTOR DEVICE

(71) Applicant: ROHM CO., LTD., Kyoto-shi (JP)

(72) Inventors: Seigo MORI, Kyoto-shi (JP); Yuki NAKANO, Kyoto-shi (JP)

(73) Assignee: ROHM CO., LTD., Kyoto-shi (JP)

(21) Appl. No.: 19/440,710

(22) Filed: Jan. 6, 2026

Related U.S. Application Data
(63) Continuation of application No. PCT/JP2024/021287, filed on Jun. 12, 2024.

(30) Foreign Application Priority Data
Jul. 20, 2023 (JP) 2023-118661

(51) Int. Cl. H10D 30/66; H10D 12/00; H10D 12/01; H10D 30/01; H10D 62/10; H10D 62/60; H10D 62/832

(52) U.S. Cl. CPC H10D 30/668; H10D 12/415; H10D 12/481; H10D 30/665; H10D 62/102; H10D 62/126; H10D 62/60; H10D 62/8325; H10D 12/038; H10D 30/0297

(57) ABSTRACT

A semiconductor device includes a chip having a first principal surface, a first impurity region of a first conductivity type formed in a surface layer portion of the first principal surface, a second impurity region of a second conductivity type formed in a surface layer portion of the first impurity region, and a third impurity region of the first conductivity type formed in a surface layer portion of the second impurity region. A plurality of trenches are arranged at intervals in a first direction and extend in a second direction intersecting the first direction. First and second electric field relaxation structures of the second conductivity type are formed integrally with the second impurity region, are in contact with the trenches, are disposed on opposite sides of the trenches in the first direction, and are alternately arranged along the second direction.

### CROSS-REFERENCE TO RELATED APPLICATIONS

The present application is a bypass continuation application of International Patent Application No. PCT/JP 2024/021287, filed on Jun. 12, 2024, which corresponds to Japanese Patent Application No. 2023-118661, filed on Jul. 20, 2023 with the Japan Patent Office, and the entire disclosure of both the applications is incorporated herein by reference.

### TECHNICAL FIELD

The present disclosure relates to a semiconductor device.

### BACKGROUND ART

Patent Literature 1 (US 2015/0028351 A1 Specification) discloses an electronic device having an impurity region introduced into a silicon carbide layer by a channeling implantation method.

### BRIEF DESCRIPTION OF DRAWINGS

FIG. 1 is a plan view showing a semiconductor device according to a preferred embodiment of the present disclosure.

FIG. 2 is a sectional view taken along line II-II shown in FIG. 1.

FIG. 3 is a plan view showing a layout example of a chip.

FIG. 4 is a perspective view showing the layout example of the chip.

FIG. 5 is a plan view showing an active region and a trench structure.

FIG. 6 is a sectional view taken along line VI-VI shown in FIG. 5.

FIG. 7 is a sectional perspective view corresponding to FIG. 6.

FIG. 8 is a sectional view taken along line VIII-VIII shown in FIG. 5.

FIG. 9 is a sectional perspective view corresponding to FIG. 8.

FIG. 10 is a perspective view showing an arrangement of an outer peripheral region.

FIG. 11 is a sectional view showing a principal portion of the outer peripheral region.

FIG. 12 is a schematic view showing a wafer used in manufacture of the semiconductor device.

FIG. 13 is a flowchart showing a manufacturing method example of the semiconductor device.

FIG. 14A to FIG. 14H are views showing the manufacturing method example of the semiconductor device.

FIG. 15 is a view showing a first modification example of the semiconductor device.

FIG. 16 is a sectional view taken along line XVI-XVI shown in FIG. 15.

FIG. 17 is a view showing a second modification example of the semiconductor device.

FIG. 18 is a sectional view taken along line XVIII-XVIII shown in FIG. 17.

FIG. 19 is a view showing a third modification example of the semiconductor device.

FIG. 20 is a view showing a fourth modification example of the semiconductor device.

FIG. 21 is a view showing a fifth modification example of the semiconductor device.

FIG. 22 is a view showing a sixth modification example of the semiconductor device.

### DESCRIPTION OF EMBODIMENTS

Next, a preferred embodiment of the present disclosure shall be described in detail with reference to the attached drawings.

The attached drawings are all schematic views and are not strictly illustrated, and scales, proportions, angles and the like thereof do not always match. Identical reference signs are given to corresponding structures among the attached drawings, and duplicate descriptions thereof shall be omitted or simplified. For the structures whose description have been omitted or simplified, the description given before the omission or simplification shall apply.

When the wording “substantially equal” is used in this description, the wording includes a numerical value (shape) equal to a numerical value (shape) of a comparison target and also includes numerical errors (shape errors) in a range of ±10% on a basis of the numerical value (shape) of the comparison target. Although the wordings “first,” “second,” “third,” etc., are used in the following description, these are symbols attached to names of respective structures in order to clarify the order of description and are not attached with an intention of restricting the names of the respective structures.

In the following description, a conductivity type of a semiconductor (an impurity) is indicated using “p-type” or “n-type,” the “p-type” may be referred to as a “first conductivity type,” and the “n-type” may be referred to as a “second conductivity type.” As a matter of course, the “n-type” may be referred to as the “first conductivity type,” and the “p-type” may be referred to as the “second conductivity type” instead. The “p-type” is a conductivity type due to a trivalent element and the “n-type” is a conductivity type due to a pentavalent element. Unless noted in particular otherwise, the trivalent element is at least one type among boron, aluminum, gallium, and indium. Unless noted in particular otherwise, the pentavalent element is at least one type among nitrogen, phosphorus, arsenic, antimony, and bismuth.

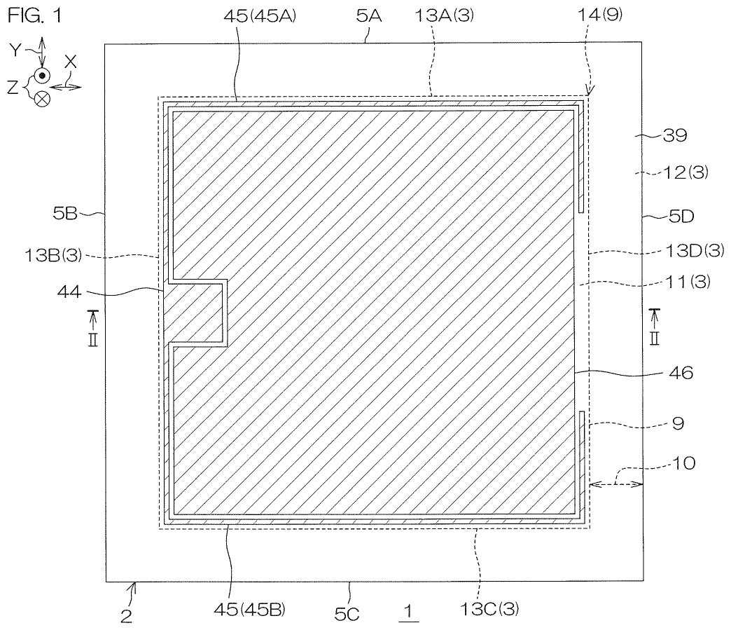

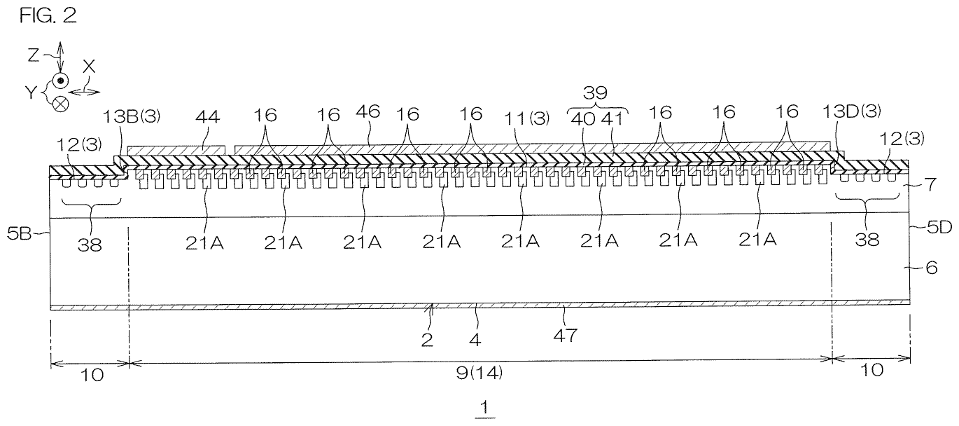

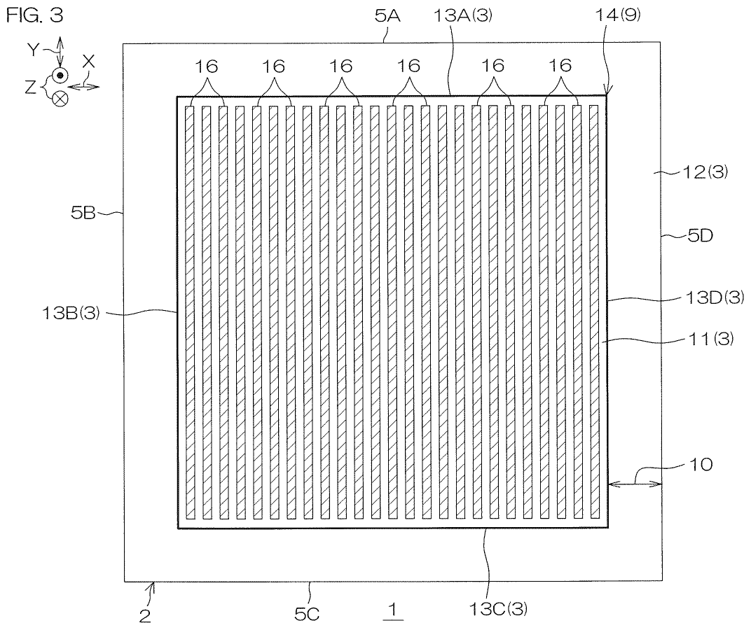

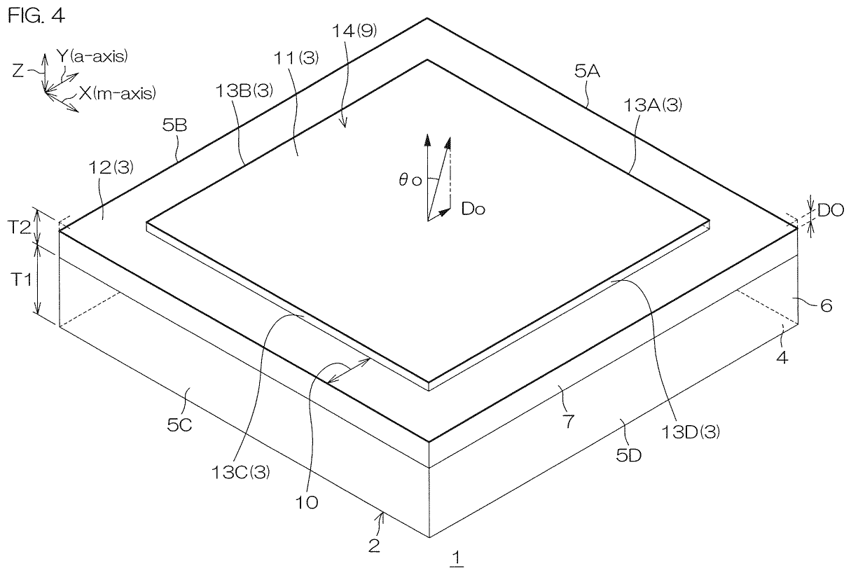

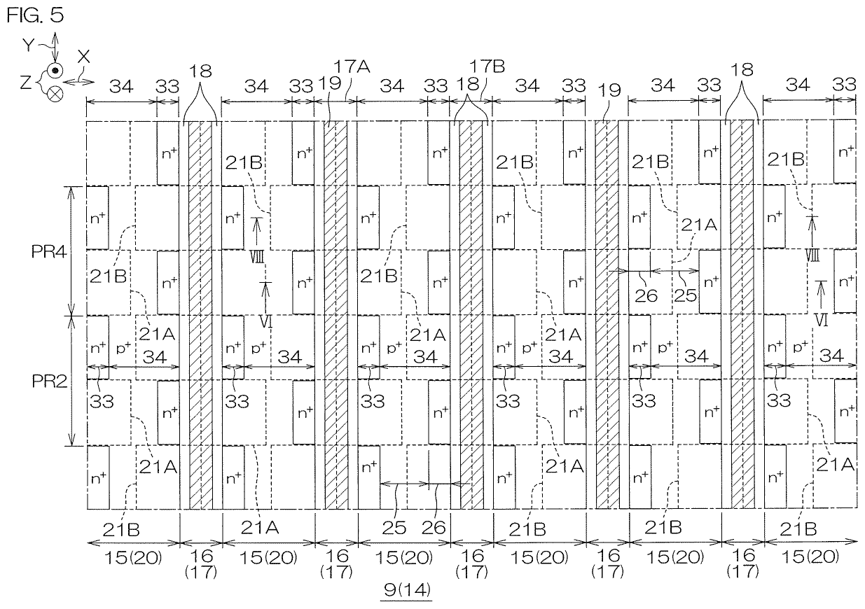

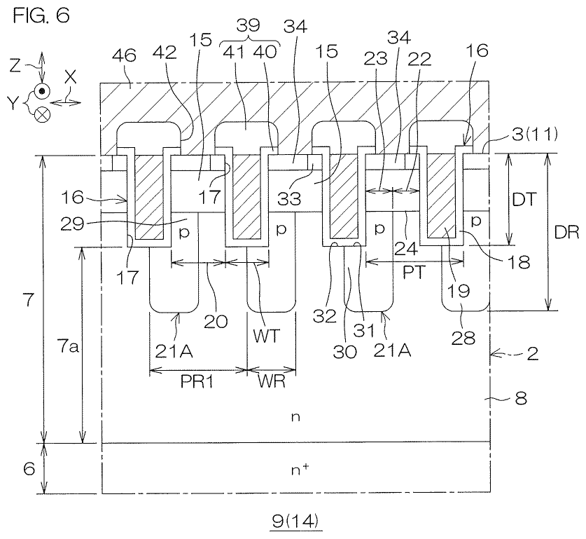

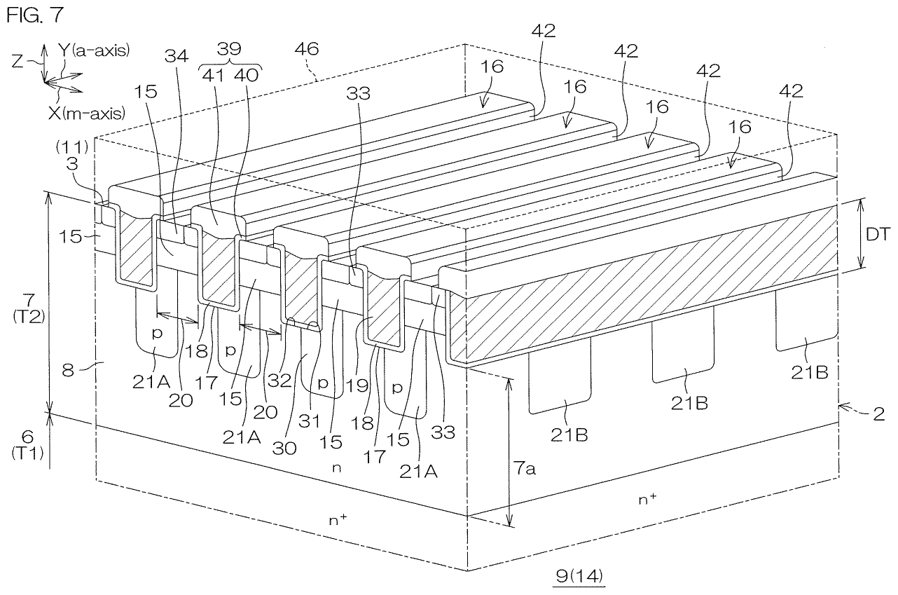

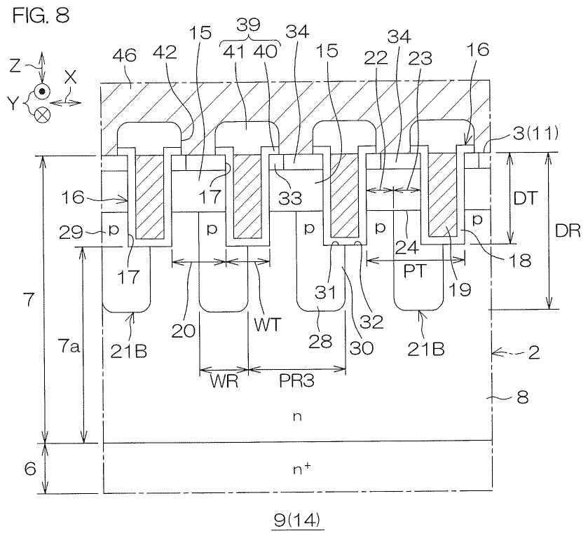

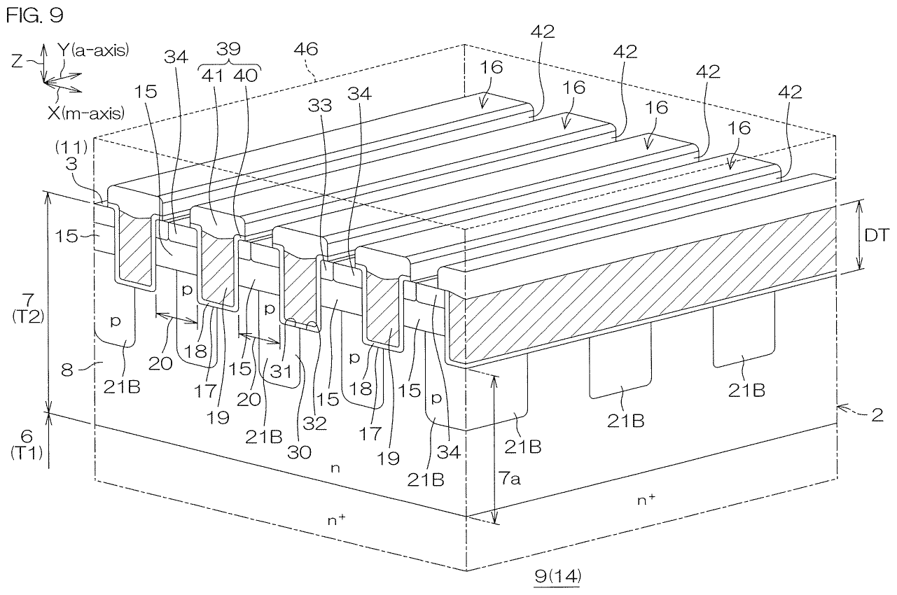

FIG. 1 is a plan view showing a semiconductor device 1 according to the preferred embodiment. FIG. 2 is a sectional view taken along line II-II shown in FIG. 1. FIG. 3 is a plan view showing a layout example of a chip 2. FIG. 4 is a perspective view showing the layout example of the chip 2. FIG. 5 is a plan view showing trench structures 16 together with an active region 9. FIG. 6 is a sectional view taken along line VI-VI shown in FIG. 5. FIG. 7 is a sectional perspective view corresponding to FIG. 6. FIG. 8 is a sectional view taken along line VIII-VIII shown in FIG. 5. FIG. 9 is a sectional perspective view corresponding to FIG. 8.

With reference to FIG. 1 to FIG. 9, the semiconductor device 1 includes the chip 2 that includes an SiC monocrystal. The chip 2 may be referred to as an “SiC chip” or a “semiconductor chip.” In this embodiment, the chip 2 is constituted of the SiC monocrystal, which is a hexagonal crystal, and is formed in a rectangular parallelepiped shape. The SiC monocrystal that is a hexagonal crystal has multiple polytypes including a 2H (hexagonal)-SiC monocrystal, a 4H-SiC monocrystal, a 6H-SiC monocrystal, etc. In this embodiment, an example in which the chip 2 is constituted of the 4H-SiC monocrystal is to be given, but the chip 2 may be constituted of another polytype instead.

The chip 2 has a first principal surface 3 on one side, a second principal surface 4 on the other side, and first to fourth side surfaces 5A to 5D connecting the first principal surface 3 and the second principal surface 4. In a plan view as viewed from a vertical direction Z (hereinafter referred to simply as “plan view”), the first principal surface 3 and the second principal surface 4 are formed in quadrilateral shapes. The vertical direction Z is also a thickness direction of the chip 2 and a normal direction to the first principal surface 3 (the second principal surface 4). The first principal surface 3 and the second principal surface 4 may be formed in a square shape or a rectangular shape in plan view.

The first principal surface 3 and the second principal surface 4 are preferably formed by c-planes of the SiC monocrystal. In this case, preferably, the first principal surface 3 is formed by a silicon plane (a (0001) plane) of the SiC monocrystal and the second principal surface 4 is formed by a carbon plane (a (000-1) plane) of the SiC monocrystal.

In regard to a circumferential direction of the chip 2 with the first side surface 5A as a starting point (counterclockwise in FIG. 1), the second side surface 5B is connected to the first side surface 5A, the third side surface 5C is connected to the second side surface 5B, and the fourth side surface 5D is connected to the first side surface 5A and the third side surface 5C. The first side surface 5A and the third side surface 5C extend in a first direction X oriented along the first principal surface 3 and are opposed in a second direction Y intersecting (specifically, orthogonal to) the first direction X. The second side surface 5B and the fourth side surface 5D extend in the second direction Y and are opposed in the first direction X.

In this embodiment, the first direction X is an m-axis direction (a [1-100] direction) of the SiC monocrystal and the second direction Y is an a-axis direction (a [11-20] direction) of the SiC monocrystal. As a matter of course, the first direction X may instead be the a-axis direction of the SiC monocrystal and the second direction Y may instead be the m-axis direction of the SiC monocrystal.

An XY plane that includes the first direction X and the second direction Y forms a horizontal plane that is orthogonal to the vertical direction Z. In the following, an axis extending along the vertical direction Z is expressed at times as a “vertical axis.” Also, in the following, the first direction X and the second direction Y is expressed at times as “horizontal directions.” Horizontal directions are also directions that extend along the first principal surface 3.

With reference to FIG. 4, the chip 2 (the first principal surface 3 and the second principal surface 4) has an off angle θo inclined at a predetermined angle in a predetermined off direction Do with respect to the c-plane of the SiC monocrystal. That is, a c-axis (a (0001) axis) of the SiC monocrystal is inclined by just the off angle θo toward the off direction Do from the vertical axis. Also, the c-plane of the SiC monocrystal is inclined by just the off angle θo with respect to the horizontal plane.

The off direction Do is preferably the a-axis direction (that is, the second direction Y) of the SiC monocrystal. The off angle θo may exceed 0°and be not more than 10°. The off angle θo may have a value belonging to any one range among exceeding 0°and not more than 1°, not less than 1° and not more than 2.5°, not less than 2.5°and not more than 5°, not less than 5° and not more than 7.5°, and not less than 7.5° and not more than 10°.

The off angle θo is preferably not more than 5°. The off angle θo is particularly preferably not less than 2° and not more than 4.5°. The off angle θo is typically set in a range of 4°±0.1°. As a matter of course, this Description does not exclude an embodiment in which the off angle θo is 0° (that is, an embodiment in which the first principal surface 3 is a just surface with respect to the c-plane).

The chip 2 includes a base layer 6 of an n-type that is constituted of an SiC monocrystal. The base layer 6 may be referred to as a “drain region,” a “base SiC layer,” a “base region,” etc. The base layer 6 extends in a layered shape in the horizontal directions and forms the second principal surface 4 and portions of the first to fourth side surfaces 5A to 5D. In this embodiment, the base layer 6 is constituted of a substrate made of the SiC monocrystal (in other words, an SiC substrate). The base layer 6 has the off direction Do and the off angle θo described above.

The base layer 6 may have an n-type impurity concentration of not less than 1×10¹⁸ cm⁻³ and not more than 1×10²¹ cm⁻³ as a peak value. The base layer 6 preferably has an n-type impurity concentration that is substantially fixed in a thickness direction. The n-type impurity concentration of the base layer 6 is preferably adjusted by a single type of pentavalent element. The n-type impurity concentration of the base layer 6 is particularly preferably adjusted by a pentavalent element other than phosphorus. In this embodiment, the n-type impurity concentration of the base layer 6 is adjusted by nitrogen.

The base layer 6 has a first thickness T1. The first thickness T1 may be not less than 5 μm and not more than 300 μm. The first thickness T1 may have a value belonging to any one range among not less than 5 μm and not more than 50 μm, not less than 50 μm and not more than 100 μm, not less than 100 μm and not more than 150 μm, not less than 150 μm and not more than 200 μm, not less than 200 μm and not more than 250 μm, and not less than 250 μm and not more than 300 μm. The first thickness T1 is preferably not less than 50 μm and not more than 250 μm.

The chip 2 includes a semiconductor layer 7 made of the SiC monocrystal that is laminated on the base layer 6. The semiconductor layer 7 as an example of a first impurity region may be referred to as a “drift region,” an “SiC layer,” a “semiconductor region,” etc. The semiconductor layer 7 extends in a layered shape in the horizontal directions and forms the first principal surface 3 and portions of the first to fourth side surfaces 5A to 5D. The semiconductor layer 7 is constituted of an epitaxial layer (that is, an SiC epitaxial layer) formed by crystal growth with the base layer 6 as a starting point.

The semiconductor layer 7 has a lower end and an upper end. The lower end of the semiconductor layer 7 is a crystal growth starting point and the upper end of the semiconductor layer 7 is a crystal growth end point. The lower end of the semiconductor layer 7 is also a bottom portion of the semiconductor layer 7. The semiconductor layer 7 is formed by continuous crystal growth from the base layer 6 and therefore, the lower end of the semiconductor layer 7 coincides with an upper end of the base layer 6.

The semiconductor layer 7 includes a drift region 8 of the n-type. In this embodiment, the drift region 8 is formed by a portion of the semiconductor layer 7 (a portion of the n-type). In more detail, the drift region 8 is formed by a portion of the semiconductor layer 7 on the second principal surface 4 side with respect to a body region 15 (to be described below) and electric field relaxation structures 21A and 21B (to be described below) in the vertical direction Z.

A boundary portion between the base layer 6 and the semiconductor layer 7 is not necessarily visually recognizable and can be evaluated and/or determined indirectly from other arrangements and elements. The semiconductor layer 7 has an off direction Do and the off angle θo that substantially coincide with the off direction Do and the off angle θo of the base layer 6.

An n-type impurity concentration of the semiconductor layer 7 (the drift region 8) is preferably less than the n-type impurity concentration of the base layer 6. The semiconductor layer 7 may have an n-type impurity concentration of not less than 1×10¹⁵ cm⁻³ and not more than 1×10¹⁸ cm⁻³ as a peak value. The n-type impurity concentration of the semiconductor layer 7 may be substantially fixed in a thickness direction. As a matter of course, the n-type impurity concentration of the semiconductor layer 7 may have a concentration gradient that increases gradually and/or decreases gradually in a lamination direction (a crystal growth direction).

In this embodiment, the n-type impurity concentration of the semiconductor layer 7 is adjusted by nitrogen. The semiconductor layer 7 may have an n-type impurity concentration that is adjusted by at least one type of pentavalent element. For example, the n-type impurity concentration of the semiconductor layer 7 may be adjusted by at least one type among nitrogen, phosphorus, arsenic, antimony, and bismuth. The semiconductor layer 7 preferably contains a pentavalent element other than phosphorus.

The semiconductor layer 7 has a second thickness T2 less than the first thickness T1. The second thickness T2 may be not less than 1 μm and not more than 10 μm. The second thickness T2 may have a value belonging to any one range among not less than 1 μm and not more than 2 μm, not less than 2μm and not more than 4μm, not less than 4 μm and not more than 6 μm, not less than 6 μm and not more than 8 μm, and not less than 8 μm and not more than 10 μm. The second thickness T2 is preferably not less than 2 μm and not more than 8 μm.

The semiconductor device 1 includes the active region 9 set in the chip 2. The active region 9 is set in an inner portion of the chip 2 at intervals from peripheral edges (the first to fourth side surfaces 5A to 5D) of the chip 2 in plan view. The active region 9 is set in a polygonal shape (in this embodiment, a quadrilateral shape) having four sides parallel to the peripheral edges of the chip 2 in plan view. A planar area of the active region 9 is preferably not less than 50% and not more than 90% of a planar area of the first principal surface 3.

The semiconductor device 1 includes an outer peripheral region 10 that, in the chip 2, is set outside the active region 9. The outer peripheral region 10 is provided in a region between the peripheral edges of the chip 2 and the active region 9 in plan view. The outer peripheral region 10 extends in a band shape along the active region 9 and is set to a polygonal annular shape (in this embodiment, a quadrilateral annular shape) that surrounds the active region 9 in plan view.

The semiconductor device 1 includes an active surface 11, an outer surface 12, and first to fourth connecting surfaces 13A to 13D that are formed in the first principal surface 3. The active surface 11, the outer surface 12, and the first to fourth connecting surfaces 13A to 13D demarcate an active mesa 14 in the first principal surface 3.

The active surface 11 may be referred to as a “first surface portion,” the outer surface 12 may be referred to as a “second surface portion,” the first to fourth connecting surfaces 13A to 13D may be referred to as “connecting surface portions,” and the active mesa 14 may be referred to as an “active mesa portion.” The active surface 11, the outer surface 12, and the first to fourth connecting surfaces 13A to 13D (that is, the active mesa 14) may be considered as components of the chip 2 (the first principal surface 3).

The active surface 11 is formed in the active region 9. That is, the active surface 11 is formed at intervals inward from the peripheral edges of the first principal surface 3 (from the first to fourth side surfaces 5A to 5D). The active surface 11 has a flat surface extending in the first direction X and the second direction Y. In this embodiment, the active surface 11 is formed by the c-plane (an Si plane). In this embodiment, the active surface 11 is formed in a quadrilateral shape having four sides parallel to the first to fourth side surfaces 5A to 5D in plan view.

The outer surface 12 is formed in the outer peripheral region 10. That is, the outer surface 12 is formed outside the active surface 11. The outer surface 12 is recessed in the thickness direction of the chip 2 (toward the second principal surface 4 side) with respect to the active surface 11. Specifically, in this embodiment, the outer surface 12 is recessed to a depth less than the thickness of the semiconductor layer 7 such as to expose the semiconductor layer 7. That is, the outer surface 12 faces the base layer 6 with a portion of the semiconductor layer 7 interposed therebetween and exposes the semiconductor layer 7.

The outer surface 12 extends in a band shape along the active surface 11 in plan view and is formed in an annular shape (specifically, a quadrilateral annular shape) surrounding the active surface 11. The outer surface 12 has a flat surface extending in the first direction X and the second direction Y and is formed substantially parallel to the active surface 11. In this embodiment, the outer surface 12 is formed by the c-plane (the Si plane). The outer surface 12 is continuous to the first to fourth side surfaces 5A to 5D.

The outer surface 12 has an outer peripheral depth DO. The outer peripheral depth DO may be not less than 0.1 μm and not more than 2 μm. The outer peripheral depth DO may have a value belonging to any one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.5 μm, and not less than 1.5 μm and not more than 2 μm. The outer peripheral depth DO is preferably not less than 0.1 μm and not more than 1.5 μm.

The first to fourth connecting surfaces 13A to 13D extend in the vertical direction Z and connect the active surface 11 and the outer surface 12. The first connecting surface 13A is positioned at the first side surface 5A side, the second connecting surface 13B is positioned at the second side surface 5B side, the third connecting surface 13C is positioned at the third side surface 5C side, and the fourth connecting surface 13D is positioned at the fourth side surface 5D side. The first connecting surface 13A and the third connecting surface 13C extend in the first direction X and are opposed in the second direction Y. The second connecting surface 13B and the fourth connecting surface 13D extend in the second direction Y and are opposed in the first direction X.

The first to fourth connecting surfaces 13A to 13D may extend substantially vertically between the active surface 11 and the outer surface 12 such as to demarcate the active mesa 14 of a quadrilateral columnar shape. The first to fourth connecting surfaces 13A to 13D may be inclined obliquely downward from the active surface 11 toward the outer surface 12 to demarcate the active mesa 14 having a quadrilateral pyramid shape. The active mesa 14 is thus demarcated in a projecting shape on the semiconductor layer 7 in the first principal surface 3. The active mesa 14 is formed just on the semiconductor layer 7 and is not formed on the base layer 6.

With reference to FIG. 5 to FIG. 9, the semiconductor device 1 includes the body region 15 of the p-type formed in a surface layer portion of the first principal surface 3 (the active surface 11). In this embodiment, the body region 15 as an example of a second impurity region is formed in a layered shape extending along the active surface 11. The body region 15 may be formed in an entirety of the active surface 11 and may be exposed from the first to fourth connecting surfaces 13A to 13D. The body region 15 is formed at an interval to the active surface 11 side from the lower end of the semiconductor layer 7. The body region 15 is preferably formed at an interval to the active surface 11 side from a depth position of the outer surface 12 and is exposed from the active surface 11.

The body region 15 may have a p-type impurity concentration of not less than 1×10¹⁵ cm⁻³ and not more than 1×10¹⁸ cm⁻³ as a peak value. The p-type impurity concentration of the body region 15 is preferably adjusted by at least one type of trivalent element. The trivalent element of the body region 15 may be at least one type among boron, aluminum, gallium, and indium.

The semiconductor device 1 includes the plurality of trench structures 16 of a trench electrode type that are formed in the first principal surface 3 (the active surface 11) in the active region 9. The trench structures 16 may be referred to as “gate structures,” “trench gate structures,” etc. A gate potential is applied as a control potential to the plurality of trench structures 16. The plurality of trench structures 16 control inversion and non-inversion of channels (current paths) inside the body region 15 in response to the gate potential.

The plurality of trench structures 16 are arranged at intervals inward from peripheral edges of the active surface 11 (from the first to fourth connecting surfaces 13A to 13D) in the active region 9. In this embodiment, the plurality of trench structures 16 are arranged at intervals in the first direction X and are each formed in a band shape extending in the second direction Y.

That is, the plurality of trench structures 16 are arranged at intervals in the m-axis direction and each extend in the a-axis direction. Also, in this embodiment, the plurality of trench structures 16 are arranged as stripes extending in the a-axis direction (the second direction Y). An extension direction of the plurality of trench structures 16 coincides with the off direction Do of the semiconductor layer 7.

The plurality of trench structures 16 are formed at intervals to the first principal surface 3 (the active surface 11) side from the lower end of the semiconductor layer 7 (from the base layer 6) and faces the base layer 6 with a portion of the semiconductor layer 7 interposed therebetween. The plurality of trench structures 16 demarcate a lower region 7a in a region between bottom walls of the plurality of trench structures 16 and the lower end of the semiconductor layer 7 (the base layer 6).

Each trench structure 16 has a trench width WT in an arrangement direction and has a trench depth DT in the vertical direction Z. The trench width WT is preferably less than the second thickness T2 of the semiconductor layer 7. The trench width WT may be not less than 0.1 μm and not more than 5 μm.

The trench width WT may have a value belonging to any one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.5 μm, not less than 1.5 μm and not more than 2 μm, not less than 2 μm and not more than 2.5μm, not less than 2.5μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The trench depth DT is preferably less than the second thickness T2 of the semiconductor layer 7. The trench depth DT is particularly preferably substantially equal to the outer peripheral depth DO described above. As a matter of course, the trench depth DT may be not less than the outer peripheral depth DO or may be less than the outer peripheral depth DO.

The trench depth DT is preferably greater than the trench width WT. That is, each of the plurality of trench structures 16 preferably has an aspect ratio DT/WT of extending in a vertically long columnar shape. The aspect ratio DT/WT is a ratio of the trench width WT with respect to the trench depth DT. The trench depth DT may be not less than 0.1 μm and not more than 5 μm.

The trench depth DT may have a value belonging to any one range among not less than 0.1 μm and not more than 0.25 μm, not less than 0.25 μm and not more than 0.5 μm, not less than 0.5 μm and not more than 1 μm, not less than 1 μm and not more than 1.5 μm, not less than 1.5 μm and not more than 2 μm, not less than 2 μm and not more than 3 μm, not less than 3 μm and not more than 4 μm, and not less than 4 μm and not more than 5 μm. The trench depth DT is preferably not less than 0.1 μm and not more than 1.5 μm, and more preferably not less than 0.5 μm and not more than 1.5 μm.

The plurality of trench structures 16 are arranged at intervals, each of a trench pitch PT, in the first direction X. The trench pitch PT is preferably less than the second thickness T2 of the semiconductor layer 7. The trench pitch PT is preferably less than the trench depth DT. The trench pitch PT may be not less than 0.1 μm and not more than 5 μm.

The trench pitch PT may have a value belonging to any one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm. The trench pitch PT is preferably not less than 0.5 μm and not more than 3 μm, and more preferably not less than 0.5 μm and not more than 1.5 μm.

Each trench structure 16 includes a trench 17, an insulating film 18, and an embedded electrode 19. The trench 17 is formed in the active surface 11 and demarcates wall surfaces (side walls and a bottom wall) of the trench structure 16. A bottom wall of the trench 17 preferably has a portion that extends flatly. A mesa portion 20 formed by a portion of the semiconductor layer 7 is formed between the trenches 17 that are mutually adjacent. The mesa portion 20 may be referred to as an “element mesa portion.” In this embodiment, a plurality of the trenches 17 and a plurality of the mesa portions 20 are each formed in a band shape extending along the second direction Y and are alternately arranged in the first direction X. The plurality of trenches 17 and the plurality of mesa portions 20 are arranged as stripes as a whole.

A flat portion of the bottom wall of the trench 17 particularly preferably extends substantially parallel to the first principal surface 3. That is, the bottom wall of the trench 17 preferably has the off angle θo inclined at a predetermined angle in a predetermined off direction Do with respect to the c-plane. That is, the bottom wall of the trench 17 preferably has a flat portion that extends in the off direction Do. As a matter of course, the bottom wall of the trench 17 may instead be curved in an arcuate shape toward the lower end side of the semiconductor layer 7.

The insulating film 18 covers wall surfaces of the trench 17. The insulating film 18 may include at least one among a silicon oxide film, a silicon nitride film, and a silicon oxynitride film. In this embodiment, the insulating film 18 has a single layer structure constituted of the silicon oxide film. The insulating film 18 particularly preferably includes the silicon oxide film constituted of an oxide of the chip 2.

The embedded electrode 19 is embedded in the trench 17 and faces the channel with the insulating film 18 interposed therebetween. In this embodiment, the embedded electrode 19 faces the body region 15 with the insulating film 18 interposed therebetween. The embedded electrode 19 may contain a conductive polysilicon of the p-type or the n-type.

The semiconductor device 1 includes a plurality of electric field relaxation structures 21A and 21B of the p-type that are formed at intervals in the horizontal directions inside the semiconductor layer 7. Specifically, the plurality of electric field relaxation structures 21A and 21B are formed in the mesa portions 20 and the lower region 7a inside the semiconductor layer 7. The plurality of electric field relaxation structures 21A and 21B are formed in a thickness range between the lower end of the semiconductor layer 7 and the bottom walls of the plurality of trench structures 16. In this embodiment, the plurality of electric field relaxation structures 21A and 21B include a plurality of the first electric field relaxation structures 21A and a plurality of the second electric field relaxation structures 21B.

With reference to FIG. 5 to FIG. 7, inside the lower region 7a, the plurality of first electric field relaxation structures 21A are arranged at intervals in the first direction X and at intervals in the second direction Y. Each first electric field relaxation structure 21A may be formed in a quadrilateral shape in plan view. That is, the plurality of first electric field relaxation structures 21A are arranged at intervals in the m-axis direction and arranged at intervals in the a-axis direction of the SiC monocrystal.

With reference to FIG. 6, the plurality of first electric field relaxation structures 21A are arranged at intervals, each of a first relaxation pitch PR1, in the first direction X. The first relaxation pitch PR1 may be equal to the trench pitch PT. With reference to FIG. 5, the plurality of first electric field relaxation structures 21A are arranged at intervals, each of a second relaxation pitch PR2, in the second direction Y. The second relaxation pitch PR2 may be equal to the first relaxation pitch PR1.

The first relaxation pitch PR1 and the second relaxation pitch PR2 may have a value belonging to any one range among not less than 0.25 μm and not more than 0.5 μm, not less than 0.5 μm and not more than 0.75 μm, not less than 0.75 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm. The first relaxation pitch PR1 and the second relaxation pitch PR2 are preferably not less than 0.5 μm and not more than 3.0 μm.

The first electric field relaxation structures 21A are each formed integrally with the body region 15 and is formed on one side in the first direction X with respect to the trench 17. In this embodiment, each first electric field relaxation structure 21A extends more downwardly than the bottom wall of the trench 17 in the vertical direction Z from a portion of the body region 15 sandwiched between the two trenches 17 that are mutually adjacent, widens along the horizontal directions oriented along the first principal surface 3, and overlaps the bottom wall of the trench 17.

Each first electric field relaxation structure 21A covers the bottom wall of the trench 17. In other words, each first electric field relaxation structure 21A forms at least a portion of each of a side wall and a bottom wall of one trench 17 among a pair of trenches 17 that face each other, and is in contact with the insulating film 18. Each first electric field relaxation structure 21A has, inside each trench 17, an exposed surface of a substantially L-shape that is exposed as a lower portion of the side wall of the corresponding trench 17 and as the bottom wall of the corresponding trench 17 which continues to the lower portion of the side wall.

With reference to FIG. 5, FIG. 8, and FIG. 9, inside the lower region 7a, the plurality of second electric field relaxation structures 21B are arranged at intervals in the first direction X and arranged at intervals in the second direction Y. Each second electric field relaxation structure 21B may be formed in a quadrilateral shape in plan view. That is, the plurality of second electric field relaxation structures 21B are arranged at intervals in the m-axis direction and arranged at intervals in the a-axis direction of the SiC monocrystal.

With reference to FIG. 8, the plurality of second electric field relaxation structures 21B are arranged at intervals, each of a third relaxation pitch PR3, in the first direction X. The third relaxation pitch PR3 may be equal to both the first relaxation pitch PR1 and the trench pitch PT. With reference to FIG. 5, the plurality of second electric field relaxation structures 21B are arranged at intervals, each of a fourth relaxation pitch PR4, in the second direction Y. The fourth relaxation pitch PR4 may be equal to both the second relaxation pitch PR2 and the third relaxation pitch PR3.

The third relaxation pitch PR3 and the fourth relaxation pitch PR4 may have a value belonging to any one range among not less than 0.25 μm and not more than 0.5 μm, not less than 0.5 μm and not more than 0.75 μm, not less than 0.75 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm. The third relaxation pitch PR3 and the fourth relaxation pitch PR4 are preferably not less than 0.5 μm and not more than 3.0 μm.

The second electric field relaxation structures 21B are each formed integrally with the body region 15 and is formed on the other side in the first direction X with respect to the trench 17. In this embodiment, each second electric field relaxation structure 21B extends more downwardly than the bottom wall of the trench 17 in the vertical direction Z from a portion of the body region 15 sandwiched between the two trenches 17 that are mutually adjacent, widens along the horizontal directions along the first principal surface 3, and overlaps the bottom wall of the trench 17.

Each second electric field relaxation structure 21B covers the bottom wall of the trench 17. In other words, each second electric field relaxation structure 21B forms at least a portion of each of a side wall (a side wall on an opposite side to the first electric field relaxation structure 21A) and a bottom wall of the other trench 17 among the pair of trenches 17 that face each other, and is in contact with the insulating film 18. Each second electric field relaxation structure 21B has, inside each trench 17, an exposed surface of a substantially L-shape that is exposed as a lower portion of the side wall of the corresponding trench 17 and as the bottom wall of the corresponding trench 17 which continues to the lower portion of the side wall.

In this embodiment, regarding each trench 17, the plurality of first electric field relaxation structures 21A and the plurality of second electric field relaxation structures 21B are alternately arranged along the second direction Y. With reference to FIG. 5, in plan view, the first electric field relaxation structures 21A protruding from the respective trenches 17 to one side in the first direction X and the second electric field relaxation structures 21B protruding to the other side in the first direction X (an opposite side to the first electric field relaxation structures 21A) are alternately arranged along the second direction Y.

In this embodiment, the plurality of trenches 17 are arranged at intervals in the first direction X. A layout of the plurality of first electric field relaxation structures 21A and the plurality of second electric field relaxation structures 21B which are formed at the pair of trenches 17 that are mutually adjacent shall be described.

For convenience, in FIG. 5, a pair of trenches 17 that are mutually adjacent among the plurality of trenches 17 are selectively picked up, one trench 17 is denoted as a first trench 17A, and the other trench 17 is denoted as a first trench 17B. As a matter of course, although not shown, a pair of trenches 17 that are mutually adjacent and are not defined as the first trenches 17A and 17B may be defined as the first trenches 17A and 17B.

With reference to FIG. 5, the second electric field relaxation structure 21B of the first trench 17B is arranged at a position adjacent to, in the first direction X, a region between the plurality of first electric field relaxation structures 21A of the first trench 17A. In other words, the first electric field relaxation structure 21A of the first trench 17B is arranged at a position adjacent to, in the first direction X, a region between the plurality of second electric field relaxation structures 21B of the first trench 17B.

In each mesa portion 20, the plurality of first electric field relaxation structures 21A of the first trench 17A and the plurality of second electric field relaxation structures 21B of the first trench 17B are thereby arranged alternately along the second direction Y. The plurality of first electric field relaxation structures 21A of the first trench 17A and the plurality of second electric field relaxation structures 21B of the first trench 17B do not have to overlap each other in the second direction Y as shown in FIG. 5, or may partially overlap each other.

Also, in this embodiment, in each first trench 17A or 17B, the plurality of first electric field relaxation structures 21A and the plurality of second electric field relaxation structures 21B are arranged without intervals along the second direction Y. In each mesa portion 20, the plurality of first electric field relaxation structures 21A of the first trench 17A and the plurality of second electric field relaxation structures 21B of the first trench 17B are thereby arranged without intervals along the second direction Y. In other words, an end portion of each first electric field relaxation structure 21A of the first trench 17A in the second direction Y and an end portion of each second electric field relaxation structure 21B of the first trench 17B in the second direction Y may be arranged side by side in a rectilinear shape along the first direction X. Also, the first electric field relaxation structures 21A of the first trench 17A may partially overlap the second electric field relaxation structures 21B of the first trench 17B in the first direction X.

Also, in this embodiment, the first electric field relaxation structures 21A of the plurality of trenches 17 are arranged in a rectilinear shape along the first direction X. Similarly, the second electric field relaxation structures 21B of the plurality of trenches 17 are arranged in a rectilinear shape along the first direction X. The plurality of first electric field relaxation structures 21A and the plurality of second electric field relaxation structures 21B are thereby arranged in a staggered pattern as a whole in plan view.

With reference to FIG. 6 and FIG. 8, the body region 15 includes a channel portion 22 and a non-channel portion 23. The channel portion 22 is physically separated from the first electric field relaxation structure 21A and the second electric field relaxation structure 21B. A channel is formed along the wall surface of the trench 17 adjacent to the channel portion 22. The non-channel portion 23 is physically integral with the first electric field relaxation structure 21A and the second electric field relaxation structure 21B. The non-channel portion 23 has a bottom wall that is covered with the first electric field relaxation structure 21A and the second electric field relaxation structure 21B from below.

As described above, in this embodiment, in each mesa portion 20, the plurality of first electric field relaxation structures 21A of the first trench 17A and the plurality of second electric field relaxation structures 21B of the first trench 17B are arranged without intervals along the second direction Y. In each mesa portion 20, a plurality of the channel portions 22 are thereby arranged in a zigzag shape in the second direction Y.

Among the plurality of channel portions 22, the channel portion 22 along the first trench 17A is sandwiched between a pair of first electric field relaxation structures 21A in the second direction Y and is sandwiched between the first trench 17A and the second electric field relaxation structure 21B of the first trench 17B in the first direction X. On the other hand, among the plurality of channel portions 22, the channel portions 22 along the first trench 17B is sandwiched between a pair of second electric field relaxation structures 21B in the second direction Y and is sandwiched between the first trench 17B and the first electric field relaxation structure 21A of the first trench 17A in the first direction X.

That is, in this embodiment, in plan view, each channel portion 22 is surrounded on three sides by the plurality of electric field relaxation structures 21A and 21B that are formed as physically independent diffusion regions and is adjacent to the trench 17 on the remaining one side.

With reference to FIG. 6 and FIG. 8, the first electric field relaxation structure 21A and the second electric field relaxation structure 21B form a boundary portion 24 between themselves and a bottom portion of the non-channel portion 23 located between the mutually adjacent trenches 17. The boundary portion 24 divides the mesa portion 20 into the body region 15 (the non-channel portion 23) on the first principal surface 3 side and the electric field relaxation structures 21A and 21B on the second principal surface 4 side.

Since both the body region 15 (the non-channel portion 23) and the electric field relaxation structures 21A and 21B are of the p-type, the boundary portion 24 does not have to be clearly defined by image analysis (for example, SEM image analysis). That the body region 15 and the electric field relaxation structures 21A and 21B continue in the vertical direction Z may be confirmed, for example, by acquiring a profile of a p-type impurity concentration in the vertical direction Z from the first principal surface 3 toward the second principal surface 4.

With reference to FIG. 6 and FIG. 8, each electric field relaxation structure 21A or 21B may integrally include a base portion 28 further to the second principal surface 4 side than the bottom wall of the trench 17, and a protrusion portion 29 sandwiched between the two mutually adjacent trenches 17.

The base portion 28 overlaps the respective trenches 17 and crosses the side walls of the respective trenches 17 in the first direction X. The base portion 28 has an end portion projecting further to the outer side in the horizontal directions than a region directly below the mesa portion 20.

The protrusion portion 29 extends from the base portion 28 to an inside of the mesa portion 20 along the side wall of each trench 17 and is connected to a bottom portion of the body region 15. The protrusion portion 29 is formed from the bottom wall of the trench 17 to the body region 15 in the vertical direction Z.

With reference to FIG. 6 to FIG. 9, electric field relaxation structures 21A and 21B may each have an end portion 30 at a central position of the bottom wall of the trench 17 in a width direction of the trench 17. The bottom wall of the trench 17 may thereby have a first portion 31 that is formed on the non-channel portion 23 side in the width direction of the trench 17 and covered with the electric field relaxation structures 21A and 21B. Also, the bottom wall of the trench 17 may have a second portion 32 that is formed on the channel portion 22 side with respect to the first portion 31 and covered with the semiconductor layer 7 (the drift region 8). A current path can be sufficiently secured along the wall surfaces (the side wall and the bottom wall) of the trench 17 on the channel portion 22 side since a portion of the bottom wall of the trench 17 on the channel portion 22 side is covered with the drift region 8. On-resistance can thereby be reduced.

A bottom portion of each electric field relaxation structure 21A or 21B may have a planar shape parallel or substantially parallel to the first principal surface 3 in the first direction X and the second direction Y. Therefore, in this embodiment, a portion of each electric field relaxation structure 21A or 21B further to the second principal surface 4 side than the bottom wall of the trench 17 is formed in a substantially quadrilateral shape in sectional view.

A p-type impurity concentration of the electric field relaxation structures 21A and 21B is preferably higher than the p-type impurity concentration of the body region 15. The electric field relaxation structures 21A and 21B may have a p-type impurity concentration of not less than 1×10¹⁸ cm⁻³ and not more than 1×10²⁰ cm⁻³ as a peak value. The p-type impurity concentration of the electric field relaxation structures 21A and 21B may be substantially fixed in a thickness direction. As a matter of course, the p-type impurity concentration of the electric field relaxation structures 21A and 21B may have a concentration gradient that increases gradually and/or decreases gradually in the lamination direction (crystal growth direction).

The electric field relaxation structures 21A and 21B have a relaxation depth DR greater than the trench 17 in the vertical direction Z. More preferably, the relaxation depth DR of the electric field relaxation structures 21A and 21B is not less than twice the trench depth DT. As a matter of course, the relaxation depth DR may be less than twice the trench depth DT.

The relaxation depth DR may have a value belonging to any one range among exceeding 0.25 μm and not more than 0.5 μm, not less than 0.5 μm and not more than 1 μm, not less than 1 μm and not more than 1.5 μm, not less than 1.5 μm and not more than 2 μm, not less than 2 μm and not more than 3 μm, not less than 3 μm and not more than 4 μm, and not less than 4 μm and not more than 5 μm. The relaxation depth DR is preferably not less than 2 μm and not more than 3 μm, and in this case, the trench depth DT is preferably not less than 0.5 μm and not more than 1.5 μm.

The plurality of electric field relaxation structures 21A and 21B each have a relaxation width WR in the arrangement direction. The relaxation width WR may be not less than 0.25 μm and not more than 5 μm. The relaxation width WR may have a value belonging to any one range among not less than 0.25 μm and not more than 0.5 μm, not less than 0.5 μm and not more than 0.75 μm, not less than 0.75 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The semiconductor device 1 includes a plurality of source regions 33 that is formed at one side of the plurality of trench structures 16 in the surface layer portion of the first principal surface 3 (the active surface 11). The plurality of source regions 33 as an example of third impurity regions are formed in a surface layer portion of the body region 15. In this embodiment, the plurality of source regions 33 are selectively formed in the channel portion 22, of the plurality of body regions 15 including the channel portion 22 and the non-channel portion 23. Therefore, as shown in FIG. 5, the plurality of source regions 33 are arranged in a zigzag shape in the second direction Y.

The plurality of source regions 33 have a higher n-type impurity concentration (a peak value) than that of the semiconductor layer 7. The plurality of source regions 33 may have an n-type impurity concentration of not less than 1×10¹⁸ cm⁻³ and not more than 1×10²¹ cm⁻³ as a peak value.

With reference to FIG. 5, the plurality of source regions 33 are arranged at intervals in the extension direction of the corresponding trench structure 16 in plan view. The plurality of source regions 33 are formed at intervals from the bottom portion of the body region 15 toward the active surface 11 and faces the drift region 8 directly below with a portion of the body region 15 in the vertical direction Z interposed therebetween. The plurality of source regions 33, together with the plurality of drift regions 8 directly below, demarcate channels (current paths) that extend along the wall surfaces of the corresponding trench structures 16.

The semiconductor device 1 includes a plurality of contact regions 34 that are formed in regions between the plurality of trench structures 16 in the surface layer portion of the first principal surface 3 (the active surface 11). The plurality of contact regions 34 are formed in the surface layer portion of the body region 15.

The plurality of contact regions 34 have a higher p-type impurity concentration (a peak value) than the p-type impurity concentration (the peak value) of the body region 15. The plurality of contact regions 34 have a p-type impurity concentration (a peak value) higher than the p-type impurity concentration (the peak value) of the electric field relaxation structures 21A and 21B. The plurality of contact regions 34 may have a p-type impurity concentration of not less than 1×10¹⁸ cm⁻³ and not more than 1×10²¹ cm⁻³ as a peak value.

The plurality of contact regions 34 are formed in the non-channel portion 23. Each contact region 34 is interposed in a region between the source region 33 and the trench 17 in the first direction X in the mesa portion 20. In this embodiment, the contact region 34 has a first portion 25 that extends in a band shape in the extension direction of the plurality of trench structures 16 and a second portion 26 selectively protruding from the first portion 25 in the first direction X in each mesa portion 20.

The second portion 26 is interposed between the plurality of source regions 33 that are mutually adjacent in the second direction Y and is sandwiched between a pair of the source regions 33 in the second direction Y. The contact regions 34 are formed at intervals to the active surface 11 side from the bottom portion of the body region 15 and faces the drift region 8 directly below, with a portion of the body region 15 in the vertical direction Z interposed therebetween.

The source regions 33 are thus selectively formed in the channel portion 22, of the channel portion 22 and the non-channel portion 23. On the other hand, in the non-channel portion 23, the source region 33 is not formed and the contact region 34 is formed. A function of the channel portion 22 to form the current path and a function of the non-channel portion 23 to secure electrical contact with the body region 15 can thereby be divided. As a result, ON-operation can be efficiently performed.

In the non-channel portion 23, since a lower portion of the body region 15 is completely covered with the electric field relaxation structures 21A and 21B, the non-channel portion is not highly effective as a channel. Therefore, in the non-channel portion 23, potential of the body region 15 can be stabilized by forming the contact region 34 in an entirety of the surface layer portion of the body region 15.

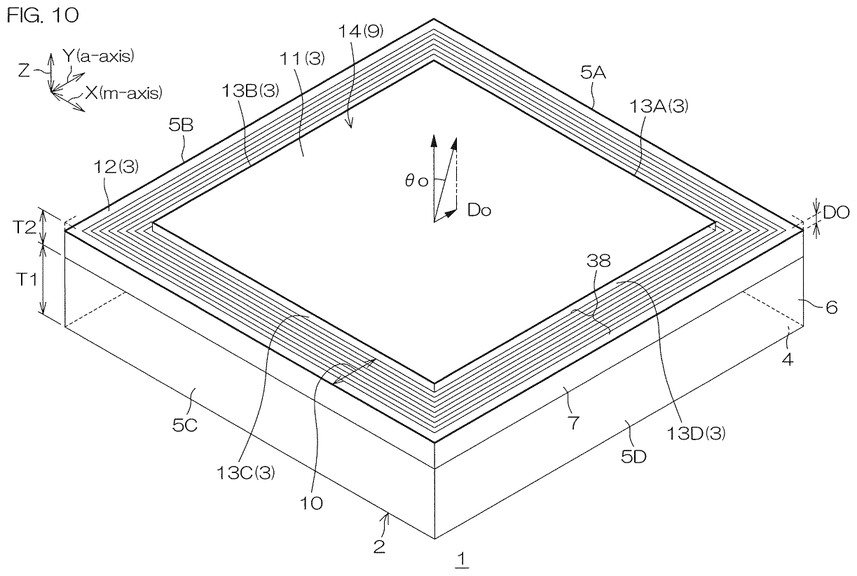

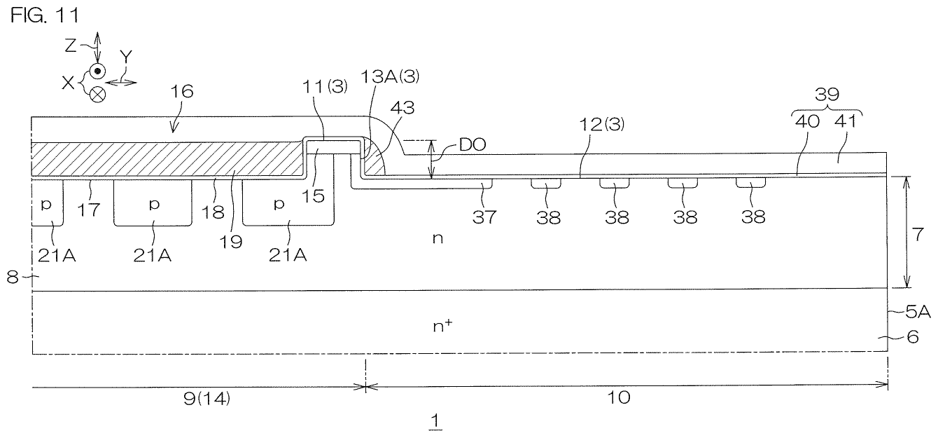

Hereinafter, an arrangement on the outer peripheral region 10 side shall be described. FIG. 10 is a perspective view showing an arrangement of the outer peripheral region 10. FIG. 11 is a sectional view showing a principal portion of the outer peripheral region 10.

The semiconductor device 1 includes a well region 37 of the p-type formed in a surface layer portion of the outer surface 12. In plan view, the well region 37 is formed at intervals to the active surface 11 side from the peripheral edges of the outer surface 12 (from the first to fourth side surfaces 5A to 5D) and extends in a band shape along the active surface 11. In this embodiment, the well region 37 is formed in an annular shape (specifically, a quadrilateral annular shape) surrounding the active surface 11 in plan view.

The well region 37 is led out from the surface layer portion of the outer surface 12 to the first to fourth connecting surfaces 13A to 13D sides and extends along surface layer portions of the first to fourth connecting surfaces 13A to 13D. The well region 37 is electrically connected to the body region 15 in the surface layer portion of the active surface 11.

The well region 37 is formed at an interval to the outer surface 12 side from the lower end of the semiconductor layer 7 and faces the base layer 6 with a portion of the semiconductor layer 7 interposed therebetween. The well region 37 forms a pn junction portion with the semiconductor region 7. The well region 37 may have a p-type impurity concentration of not less than 1×10¹⁵ cm⁻³ and not more than 1×10¹⁸ cm⁻³ as a peak value. The well region 37 has a p-type impurity concentration lower than the p-type impurity concentration of the contact region 34.

The p-type impurity concentration of the well region 37 may be higher than the p-type impurity concentration of the body region 15. As a matter of course, the p-type impurity concentration of the well region 37 may be lower than that of the body regions 15. The p-type impurity concentration of the well region 37 is preferably adjusted by at least one type of trivalent element. The trivalent element of the well region 37 may be the same kind as a trivalent element of the electric field relaxation structures 21A and 21B, or may be a kind different from the trivalent element of the electric field relaxation structures 21A and 21B. The trivalent element of the well region 37 may be at least one type among boron, aluminum, gallium, and indium.

The semiconductor device 1 includes at least one (preferably not less than two and not more than twenty) of field regions 38 of the p-type formed in the surface layer portion of the outer surface 12 (the first principal surface 3) in the outer peripheral region 10. The number of the plurality of the field regions 38 is typically not less than 4 and not more than 8. The plurality of field regions 38 are formed in an electrically floating state and relax an electric field inside the chip 2 at peripheral edge portions of the first principal surface 3. The number, width, depth, p-type impurity concentration, etc., of the field regions 38 are arbitrary and can take on any of various values in accordance with the electric field to be relaxed.

In this embodiment, the plurality of field regions 38 are arranged at intervals from the peripheral edges of the active surface 11 (from the first to fourth connecting surfaces 13A to 13D) and from the peripheral edges (the first to fourth side surfaces 5A to 5D) of the chip 2. Specifically, the plurality of field regions 38 are arranged at intervals to the peripheral edge sides of the outer surface 12 from the well region 37.

The plurality of field regions 38 are formed in band shapes extending along the active region 9 in plan view. The plurality of field regions 38 each have portions extending in a band shape in the first direction X and portions extending in a band shape in the second direction Y. In this embodiment, the plurality of field regions 38 are formed in annular shapes (specifically, quadrilateral annular shapes) surrounding the active region 9 (that is, the plurality of electric field relaxation structures 21A and 21B) in plan view. It is noted that FIG. 11 shows just the electric field relaxation structures 21A.

The plurality of field regions 38 are formed inside the semiconductor layer 7 at intervals to the outer surface 12 side from the lower end of the semiconductor layer 7 and form pn junction portions with the semiconductor layer 7. The plurality of field regions 38 preferably have bottom portions positioned at the outer surface 12 side with respect to an intermediate portion of the semiconductor layer 7 in a thickness range thereof.

In this embodiment, the plurality of field regions 38 are formed at intervals to the peripheral edge side of the chip 2 from the plurality of electric field relaxation structures 21A and 21B. Therefore, the plurality of field regions 38 do not face the plurality of electric field relaxation structures 21A and 21B in the vertical direction Z. The plurality of field regions 38 are positioned further to the second principal surface 4 side of the semiconductor layer 7 than the bottom walls of the trench structures 16.

The bottom portions of the plurality of field regions 38 may be positioned further to the first principal surface 3 side of the semiconductor layer 7 than the depth positions of the bottom portions of the plurality of electric field relaxation structures 21A and 21B. As a matter of course, the bottom portions of the plurality of field regions 38 may be positioned further to the second principal surface 4 side of the semiconductor layer 7 than the depth positions of the bottom portions of the plurality of electric field relaxation structures 21A and 21B.

The plurality of field regions 38 may have a p-type impurity concentration of not less than 1×10¹⁵ cm⁻³ and not more than 1×10¹⁸ cm⁻³ as a peak value. The p-type impurity concentration of the field region 38 may be substantially equal to the p-type impurity concentration of the body region 15. The p-type impurity concentration of the plurality of field regions 38 may be higher than the p-type impurity concentration of the body region 15. The p-type impurity concentration of the plurality of field regions 38 may be lower than the p-type impurity concentration of the body region 15.

The p-type impurity concentration of the plurality of field regions 38 is preferably adjusted by at least one type of trivalent element. The trivalent element of the field region 38 may be the same type as the trivalent element of the electric field relaxation structures 21A and 21B, or may be a type different from the trivalent element of the electric field relaxation structures 21A and 21B. The trivalent element of the field region 38 may be at least one type among boron, aluminum, gallium, and indium.

The plurality of field regions 38 preferably have a width different from the relaxation width WR of the electric field relaxation structures 21A and 21B. That is, an electric field relaxation effect by the field regions 38 is preferably adjusted separately from the plurality of electric field relaxation structures 21A and 21B. The width of the plurality of field regions 38 is particularly preferably smaller than the relaxation width WR As a matter of course, the width of the plurality of field regions 38 may be larger than the relaxation width WR. Also, the width of the plurality of field regions 38 may be substantially equal to the relaxation width WR

The plurality of field regions 38 are preferably formed at a pitch different from the relaxation pitch PR of the electric field relaxation structures 21A and 21B. The pitch of the plurality of field regions 38 is particularly preferably smaller than the relaxation pitch PR. The pitch of the plurality of field regions 38 may be larger than the relaxation pitch PR. The pitch of the plurality of field regions 38 may be substantially equal to the relaxation pitch PR.

The semiconductor device 1 includes an interlayer insulating film 39 that covers the first principal surface 3. The interlayer insulating film 39 may be referred to as an “insulating film,” an “interlayer film,” an “intermediate insulating film,” etc. In this embodiment, the interlayer insulating film 39 has a laminated structure including a first insulating film 40 and a second insulating film 41. The first insulating film 40 may include at least one among a silicon oxide film, a silicon nitride film, and a silicon oxynitride film. The first insulating film 40 particularly preferably includes the silicon oxide film constituted of the oxide of the chip 2 (the semiconductor layer 7).

The first insulating film 40 selectively covers the first principal surface 3 in the active region 9 and the outer peripheral region 10. Specifically, the first insulating film 40 selectively covers the active surface 11, the outer surface 12, and the first to fourth connecting surfaces 13A to 13D. On the active surface 11, first insulating film 40 is connected to the insulating film 18 on the active surface and exposes the embedded electrode 19.

On the outer surface 12, the first insulating film 40 covers the well region 37 and the plurality of field regions 38. In this embodiment, the first insulating film 40 is continuous to the first to fourth side surfaces 5A to 5D. As a matter of course, the first insulating film 40 may instead be formed at intervals inward from the peripheral edges of the outer surface 12 and expose the semiconductor layer 7 from peripheral edge portions of the outer surface 12. On the first to fourth connecting surfaces 13A to 13D, the first insulating film 40 covers the body region 15 and the well region 37.

The second insulating film 41 is laminated on the first insulating film 40. The second insulating film 41 may include at least one among a silicon oxide film, a silicon nitride film, and a silicon oxynitride film. The interlayer insulating film 39 preferably includes a silicon oxide film. The second insulating film 41 covers the first principal surface 3 with the first insulating film 40 interposed therebetween in the active region 9 and the outer peripheral region 10. Specifically, the second insulating film 41 selectively covers the active surface 11, the outer surface 12, and the first to fourth connecting surfaces 13A to 13D with the first insulating film 40 interposed therebetween.

In the active region 9, the second insulating film 41 covers the plurality of trench structures 16 (the embedded electrodes 19). In the outer peripheral region 10, the second insulating film 41 covers the well region 37 and the plurality of field regions 38 with the first insulating film 40 interposed therebetween. In this embodiment, the second insulating film 41 is continuous to the first to fourth side surfaces 5A to 5D. As a matter of course, the second insulating film 41 may instead be formed at intervals inward from the peripheral edges of the outer surface 12 and, together with the first insulating film 40, expose the peripheral edge portions of the first principal surface 3.

The semiconductor device 1 includes a plurality of contact openings 42 formed in the interlayer insulating film 39. The plurality of contact openings 42 include the plurality of contact openings 42 (not shown) that expose the plurality of trench structures 16 (the embedded electrodes 19) and the plurality of contact openings 42 that expose the plurality of source regions 33. The plurality of contact openings 42 for the source regions 33 are formed in regions between the plurality of trench structures 16 that are mutually adjacent and expose the plurality of source regions 33 and the plurality of contact regions 34.

The semiconductor device 1 includes a side wall structure 43 that is arranged in the interlayer insulating film 39 such as to cover at least one of the first to fourth connecting surfaces 13A to 13D. The side wall structure 43 is arranged on the first insulating film 40 and is covered with the second insulating film 41. The side wall structure 43 moderates a level difference formed between the active surface 11 and the outer surface 12.

The side wall structure 43 is formed in a band shape extending along at least one of the first to fourth connecting surfaces 13A to 13D. In this embodiment, the side wall structure 43 is formed in an annular shape (specifically, a quadrilateral annular shape) extending along the first to fourth connecting surfaces 13A to 13D such as to surround the active surface 11 in plan view.

The side wall structure 43 may have a portion extending in a film shape along the outer surface 12 and a portion extending in a film shape along the first to fourth connecting surfaces 13A to 13D. In this embodiment, the side wall structure 43 is formed at an interval from the innermost field region 38 toward the active surface 11 and faces the well region 37 with the first insulating film 40 interposed therebetween in the horizontal directions and the vertical direction Z. The side wall structure 43 may face the body region 15 with the first insulating film 40 interposed therebetween.

With reference to FIG. 1, the semiconductor device 1 includes a gate pad 44 arranged on the interlayer insulating film 39. The gate pad 44 is an electrode to which the gate potential is applied from an exterior. The gate pad 44 may be referred to as a “gate pad electrode,” a “first pad electrode,” etc. The gate pad 44 may have a laminated structure that includes a Ti-based metal film and an Al-based metal film that are laminated in that order from the interlayer insulating film 39 side.

In this embodiment, the gate pad 44 is arranged on a portion of the interlayer insulating film 39 that covers the active region 9. Specifically, the gate pad 44 is arranged on the active surface 11 at an interval from the outer surface 12 in plan view. The gate pad 44 is arranged in a region adjacent to a central portion of one side (in this embodiment, the second connecting surface 13B) of the active surface 11 in plan view.

As a matter of course, the gate pad 44 may be arranged in a region along any of central portions of the first to fourth connecting surfaces 13A to 13D. As a matter of course, the gate pad 44 may be arranged in an arbitrary corner portion of the active surface 11 in plan view. Also, the gate pad 44 may be arranged at a central portion of the active surface 11 in plan view. In this embodiment, the gate pad 44 is formed in a quadrilateral shape in plan view.

The semiconductor device 1 includes at least one (in this embodiment, a plurality) of gate wirings 45 that is led out onto the interlayer insulating film 39 from the gate pad 44. The gate wiring 45 may be referred to as a “wiring,” a “wiring electrode,” etc. In this embodiment, the plurality of gate wirings 45 are arranged on the active surface 11 at intervals from the outer surface 12 in plan view.

The plurality of gate wirings 45 may have a laminated structure that includes a Ti-based metal film and an Al-based metal film that are laminated in that order from the interlayer insulating film 39 side. In this embodiment, the plurality of gate wirings 45 include a first gate wiring 45A and a second gate wiring 45B.

The first gate wiring 45A is led out toward the first connecting surface 13A side from the gate pad 44 and extends in a line shape along the peripheral edge of the active surface 11 such as to intersect (specifically, be orthogonal to) portions (specifically, one end portions) of the plurality of trench structures 16. The first gate wiring 45A penetrates through the interlayer insulating film 39 via the plurality of contact openings 42 and is electrically connected to the one end portions of the plurality of trench structures 16.

The second gate wiring 45B is led out toward the third connecting surface 13C side from the gate pad 44 and extends in a line shape along the peripheral edge of the active surface 11 such as to intersect (specifically, be orthogonal to) portions (specifically, the other end portions) of the plurality of trench structures 16. The second gate wiring 45B penetrates through the interlayer insulating film 39 via the plurality of contact openings 42 and is electrically connected to the other end portions of the plurality of trench structures 16.

The semiconductor device 1 includes a source pad 46 arranged on the interlayer insulating film 39 at intervals from the gate pad 44 and the gate wirings 45. The source pad 46 is an electrode to which a source potential is applied from an exterior. The source pad 46 may be referred to as a “source pad electrode,” a “second pad electrode,” etc. The source pad 46 may have a laminated structure that includes a Ti-based metal film and an Al-based metal film that are laminated in that order from the interlayer insulating film 39 side.

In this embodiment, the source pad 46 is arranged on the active surface 11 at an interval from the outer surface 12 in plan view. In this embodiment, the source pad 46 is formed in a polygonal shape having a recess portion that is recessed along the gate pad 44 in plan view. As a matter of course, the source pad 46 may instead be formed in a quadrilateral shape in plan view.

The source pad 46 penetrates the interlayer insulating film 39 via the plurality of contact openings 42 and is electrically connected to the body regions 15, the plurality of source regions 33, and the plurality of contact regions 34. That is, the source pad 46 is electrically connected to the plurality of electric field relaxation structures 21A and 21B via the body region 15.

The semiconductor device 1 includes a drain pad 47 that covers the second principal surface 4. The drain pad 47 is an electrode to which a drain potential is applied from an exterior. The drain pad 47 may be referred to as a “drain pad electrode,” a “third pad electrode,” etc. The drain pad 47 forms an ohmic contact with the base layer 6 exposed from the second principal surface 4.

That is, the drain pad 47 is electrically connected to the plurality of drift regions 8 via the base layer 6. The drain pad 47 may cover an entirety of the second principal surface 4 such as to be continuous to the peripheral edges (the first to fourth side surfaces 5A to 5D) of the chip 2. The drain pad 47 may cover the second principal surface 4 at intervals inward from the peripheral edges of the chip 2 such as to expose the peripheral edge portions of the chip 2.

A breakdown voltage applicable between the source pad 46 and the drain pad 47 (between the first principal surface 3 and the second principal surface 4) may be not less than 500 V and not more than 3000 V. The breakdown voltage may have a value belonging to any one range among not less than 500 V and not more than 1000 V, not less than 1000 V and not more than 1500 V, not less than 1500 V and not more than 2000 V, not less than 2000 V and not more than 2500 V, and not less than 2500 V and not more than 3000 V.

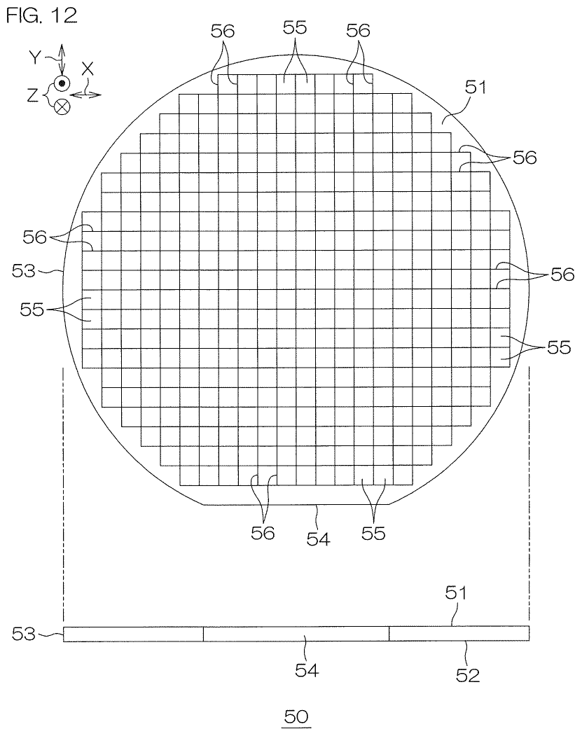

FIG. 12 is a schematic view showing a wafer 50 used in manufacture of the semiconductor device 1. The wafer 50 is a base material of the base layer 6 and contains an SiC monocrystal. The wafer 50 is formed in a flat disk shape. As a matter of course, the wafer 50 may be formed in a flat rectangular parallelepiped shape instead. The wafer 50 has a first wafer principal surface 51 on one side, a second wafer principal surface 52 on the other side, and a wafer side surface 53 connecting the first wafer principal surface 51 and the second wafer principal surface 52.

The first wafer principal surface 51 corresponds to the upper end of the base layer 6, and the second wafer principal surface 52 corresponds to a lower end of the base layer 6. The first wafer principal surface 51 and the second wafer principal surface 52 are formed by c-planes of the SiC monocrystal. The first wafer principal surface 51 is formed by a silicon plane of the SiC monocrystal, and the second wafer principal surface 52 is formed by a carbon plane of the SiC monocrystal. The wafer 50 (the first wafer principal surface 51 and the second wafer principal surface 52) has the off direction Do and the off angle θo described above.

The wafer 50 has, on the wafer side surface 53, a mark 54 that indicates a crystal orientation of the SiC monocrystal. The mark 54 may include either or both of an orientation flat and an orientation notch. The orientation flat is constituted of a notched portion that is notched rectilinearly in plan view. The orientation notch is constituted of a notched portion that is notched in a recessed shape (for example, a tapered shape) toward a central portion of the first wafer principal surface 51 in plan view.

The mark 54 may include either or both of a first orientation flat that extends in the m-axis direction and a second orientation flat that extends in the a-axis direction. The mark 54 may include either or both of an orientation notch that is recessed in the m-axis direction and an orientation notch flat that is recessed in the a-axis direction. In FIG. 12, the orientation flat that extends in the m-axis direction (the first direction X) in plan view is shown.

For example, a plurality of device regions 55 and a plurality of intended cutting lines 56 are set by alignment marks, etc., in the wafer 50. Each device region 55 is a region corresponding to the semiconductor device 1. The plurality of device regions 55 are each set in a quadrilateral shape in plan view.

In this embodiment, the plurality of device regions 55 are set in a matrix along the first direction X and the second direction Y. The plurality of device regions 55 are each set at intervals inward from a peripheral edge of the first wafer principal surface 51 in plan view. The plurality of intended cutting lines 56 are set in a lattice extending along the first direction X and the second direction Y such as to demarcate the plurality of device regions 55.

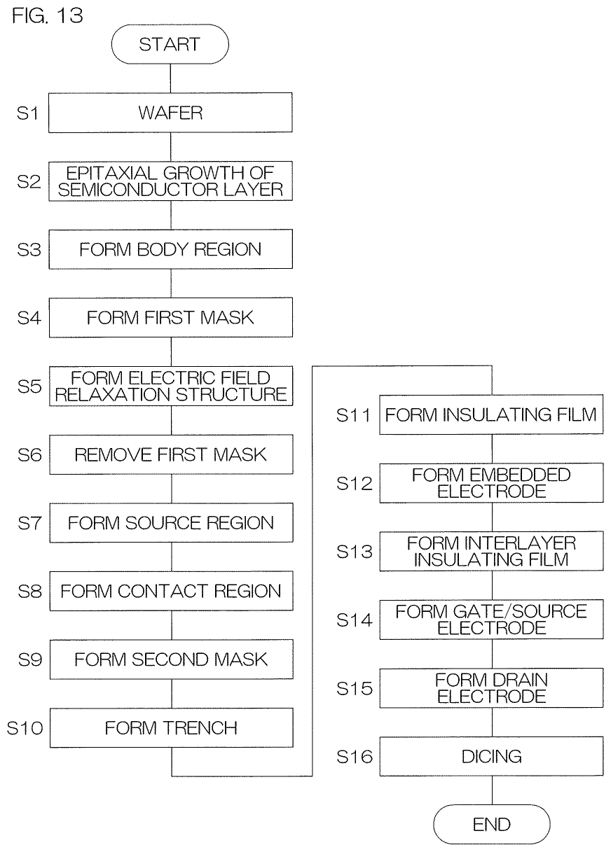

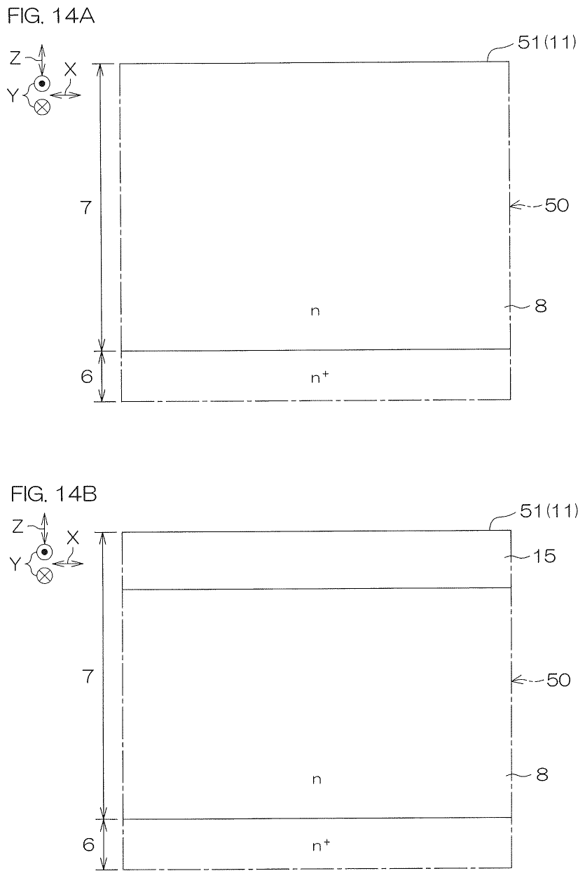

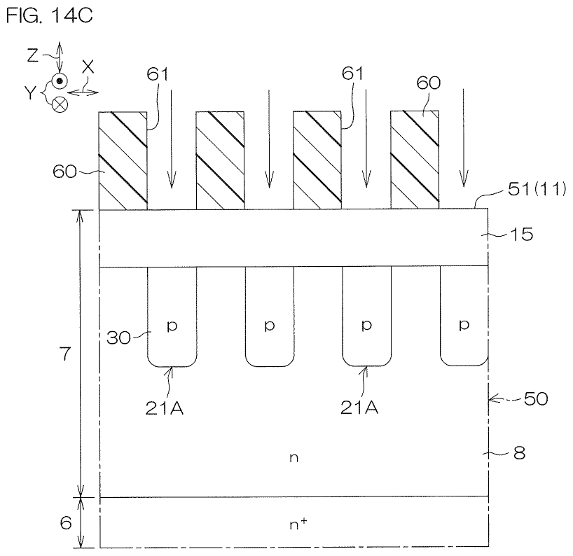

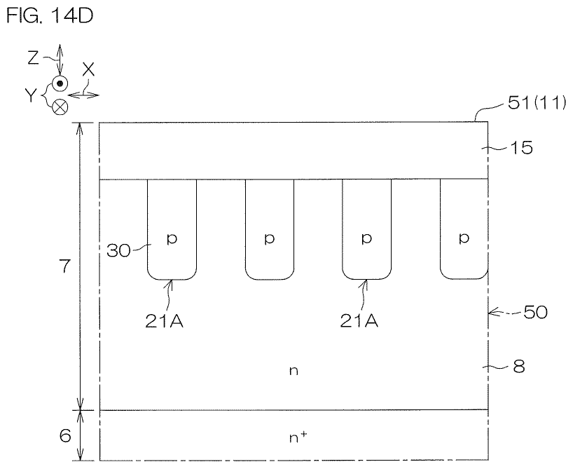

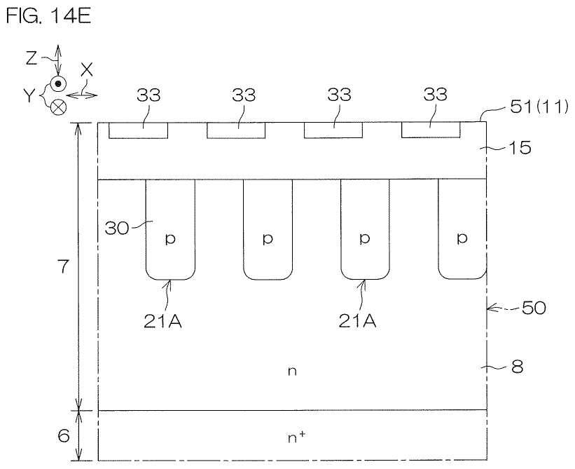

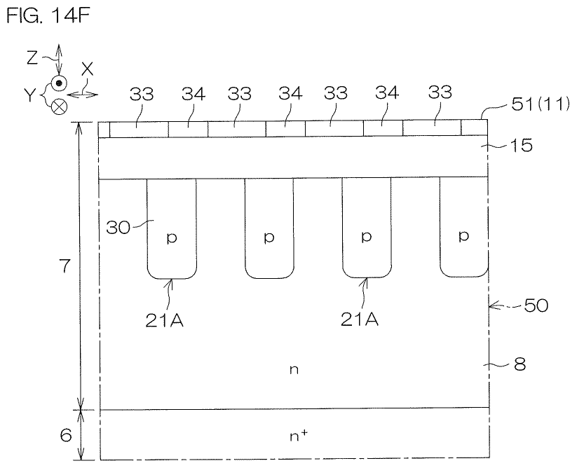

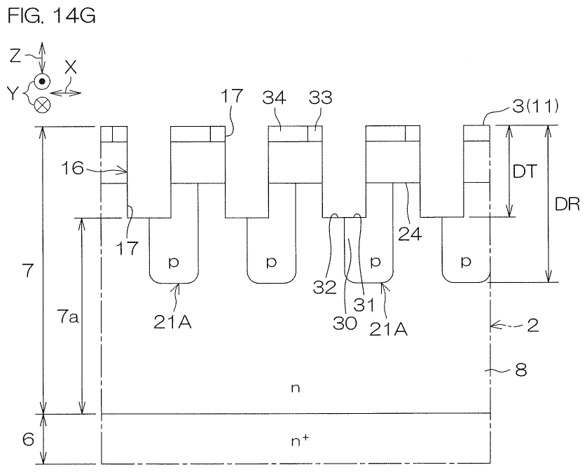

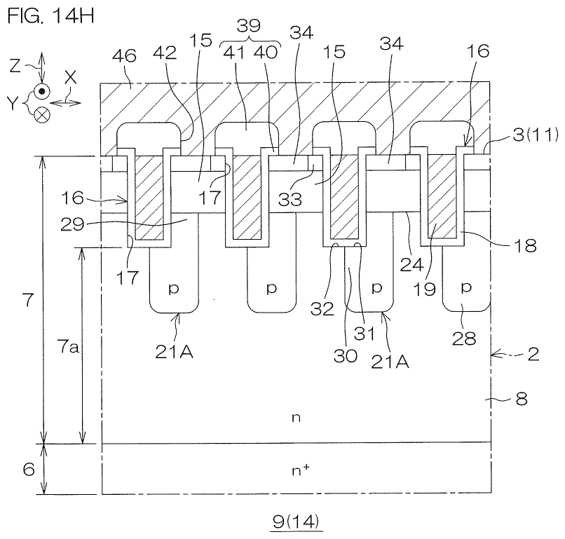

FIG. 13 is a flowchart showing a manufacturing method example of the semiconductor device 1. FIG. 14A to FIG. 14H are sectional views showing the manufacturing method example of the semiconductor device 1. FIG. 14A to FIG. 14H are sectional views corresponding to FIG. 6.

First, with reference to FIG. 14A, a preparation step of the wafer 50 described above is performed (step S1 in FIG. 13). Next, a forming step of the semiconductor layer 7 is performed (step S2 in FIG. 13). The semiconductor layer 7 is formed by an epitaxial growth method with the first wafer principal surface 51 (the wafer 50) as a starting point.

Next, with reference to FIG. 14B, a forming step of the body region 15 is performed (step S3 in FIG. 13). In the forming step of the body region 15, a p-type impurity is introduced into an entirety of the semiconductor layer 7. The body region 15 are thereby be formed in an entirety of the surface layer portion of the semiconductor layer 7.

Next, with reference to FIG. 14C, a forming step of a first mask 60 having a predetermined pattern is performed (step S4 in FIG. 13). The first mask 60 is preferably an inorganic mask (a hard mask). The first mask 60 is arranged on the upper end of the semiconductor layer 7 and has a plurality of first openings 61 that expose regions in which the plurality of electric field relaxation structures 21A and 21B are to be formed. Next, a forming step of the plurality of electric field relaxation structures 21A and 21B is performed (step S5 in FIG. 13). In the forming step of the electric field relaxation structures 21A and 21B, the p-type impurity is selectively introduced into the semiconductor layer 7 via the first mask 60. The electric field relaxation structures 21A and 21B connected to the lower portion of the body region 15 is thereby formed.

As a forming method of the electric field relaxation structures 21A and 21B, various ion implantation methods can be applied. For example, the electric field relaxation structures 21A and 21B may be formed by a channeling ion implantation method. The channeling implantation step is performed based on the data (the information) on the off angle θo. In the channeling implantation step, the electric field relaxation structures 21A and 21B can be selectively and easily formed at a deep position of the semiconductor layer 7. In a case where the electric field relaxation structures 21A and 21B are formed by the channeling ion implantation method, the electric field relaxation structures 21A and 21B may be formed before the body region 15 is formed.

Next, with reference to FIG. 14D, the first mask 60 is removed (step S6 in FIG. 13). Next, with reference to FIG. 14E, a forming step of the plurality of source regions 33 is performed (step S7 in FIG. 13). The plurality of source regions 33 are formed by introducing an n-type impurity into the surface layer portion of the semiconductor layer 7 by an ion implantation method performed via a mask (not shown) having a predetermined layout.

Next, with reference to FIG. 14F, a forming step of the plurality of contact regions 34 is performed (step S8 in FIG. 13). The plurality of contact regions 34 are formed by introducing the p-type impurity into the surface layer portion of the semiconductor layer 7 by the ion implantation method performed via a mask (not shown) having a predetermined layout. The forming step of the contact regions 34 may be performed prior to the forming step of the source regions 33.

Next, with reference to FIG. 14G, a forming step of the plurality of trenches 17 is performed. First, a second mask (not shown) having a predetermined pattern is formed (step S9 in FIG. 13). The second mask is preferably an inorganic mask (a hard mask). Next, unnecessary portions of the semiconductor layer 7 are removed by an etching method via the second mask. The etching method may be either or both of a wet etching method and a dry etching method. The etching method is preferably an RIE (reactive ion etching) method. This allows the plurality of trenches 17 to be formed at the upper end of the semiconductor layer 7 (step S10 in FIG. 13). Also, the active surface 11, the outer surface 12, and the first to fourth connecting surfaces 13A to 13D are formed at the upper end of the semiconductor layer 7. After the forming step of the plurality of trenches 17, the second mask is removed.

Next, with reference to FIG. 14H, a forming step of the insulating films 18 is performed (step S11 in FIG. 13). The forming step of the insulating films 18 serves in common as a forming step of the first insulating film 40. The insulating films 18 may be formed by either or both of a CVD (chemical vapor deposition) method and an oxidation treatment method. The insulating films 18 and the first insulating film 40 are typically formed by a thermal oxidation treatment method. The insulating films 18 are formed in a film shape on the wall surfaces of the plurality of trenches 17, and the first insulating film 40 is formed in a film shape in a region of the upper end of the semiconductor layer 7 outside the plurality of trenches 17.

Next, a forming step of the embedded electrodes 19 is performed (step S12 in FIG. 13). This step includes a step of forming a base electrode film on the insulating films 18. In this embodiment, the base electrode film contains a conductive polysilicon. The base electrode film backfills the plurality of trenches 17 and covers the upper end of the semiconductor layer 7. The base electrode film may be formed by the CVD method. Next, unnecessary portions of the embedded electrodes 19 are removed by the etching method. The unnecessary portions of the embedded electrodes 19 are removed until the insulating films 18 are exposed. The etching method may be either or both of a wet etching method and a dry etching method. Thereby, the plurality of embedded electrodes 19 are respectively embedded inside the plurality of trenches 17 and the plurality of trench structures 16 are formed.

Next, a forming step of the interlayer insulating film 39 (the second insulating film 41) is performed (step S13 in FIG. 13). The interlayer insulating film 39 may be formed by the CVD method. The plurality of contact openings 42 having a predetermined layout are formed in the interlayer insulating film 39 by an etching method performed via a mask (not shown) having the predetermined layout.

Next, a forming step of the gate pad 44, the gate wirings 45, and the source pad 46 is performed (step S14 in FIG. 13) The gate pad 44, the gate wirings 45, and the source pad 46 are formed by depositing a metal film on the interlayer insulating film 39 by the sputtering method and thereafter forming to a predetermined layout by the etching method performed via a mask (not shown) having the predetermined layout.

Next, a forming step of the drain pad 47 is performed (step S15 in FIG. 13). The drain pad 47 is formed by depositing a metal film on the second wafer principal surface 52 by the sputtering method. Thereafter, the wafer 50 is cut along the plurality of intended cutting lines 56 (step S16 in FIG. 13). Through steps including the above, a plurality of semiconductor devices 1 are manufactured from the single wafer 50.

As described above, since the electric field relaxation structures 21A and 21B is formed on the bottom wall of the trench 17, it is possible to relax concentration of electric fields on the bottom wall of the trench 17 of the trench gate structure according to the MISFET (metal insulator semiconductor field effect transistor).

In this embodiment, as shown in FIG. 5, the plurality of first electric field relaxation structures 21A of the first trench 17A and the plurality of second electric field relaxation structures 21B of the first trench 17B are alternately arranged along the second direction Y in each mesa portion 20. That is, the plurality of first electric field relaxation structures 21A and the plurality of second electric field relaxation structures 21B are arranged in a staggered pattern as a whole in plan view. Each channel portion 22 is thereby sandwiched between the electric field relaxation structures 21A and 21B from both sides in each of the first direction X and the second direction Y and is surrounded by the electric field relaxation structures 21A and 21B. As a result, since electric field relaxation can be performed from the upper, lower, left, and right sides of each channel portion 22, the relaxation effect of the concentration of electric fields on the insulating film 18 of the trench 17 of the trench gate structure.

For example, in an embodiment in which the band-shaped electric field relaxation structures 21A and 21B that extend in the second direction Y are selectively formed just on one side in the width direction of the respective trenches 17, the electric field relaxation can just be performed from both sides in the first direction X (both left and right sides of sheet surface). On the other hand, in the embodiment in FIG. 5, since the electric field can be relaxed from the upper, lower, left, and right sides of each channel portion 22, the concentration of electric fields on the insulating film 18 of the trench 17 can be relaxed effectively.

Also, in each mesa portion 20, the plurality of first electric field relaxation structures 21A of the first trench 17A and the plurality of second electric field relaxation structures 21B of the first trench 17B are arranged without intervals along the second direction Y. The electric field relaxation effect can thereby be further improved since the plurality of first electric field relaxation structures 21A and the plurality of second electric field relaxation structures 21B can be close to each other to be densely arranged.

Also, a portion of the body region 15 which is physically integral with the electric field relaxation structures 21A and 21B is covered with a portion of the second conductivity type (the body region 15 and the electric field relaxation structures 21A and 21B) from the side wall to the bottom wall of the trench 17. Since a range in which an inversion layer is to be formed along an inner wall of the trench 17 becomes prolonged, a voltage (a threshold voltage) necessary for channel formation is likely to be selectively high as compared with that of the channel portion 22. Thus, a variation in a threshold voltage of the semiconductor device 1 can be reduced by forming, as the non-channel portion 23, a portion of the body region 15 which is physically integral with the electric field relaxation structures 21A and 21B.

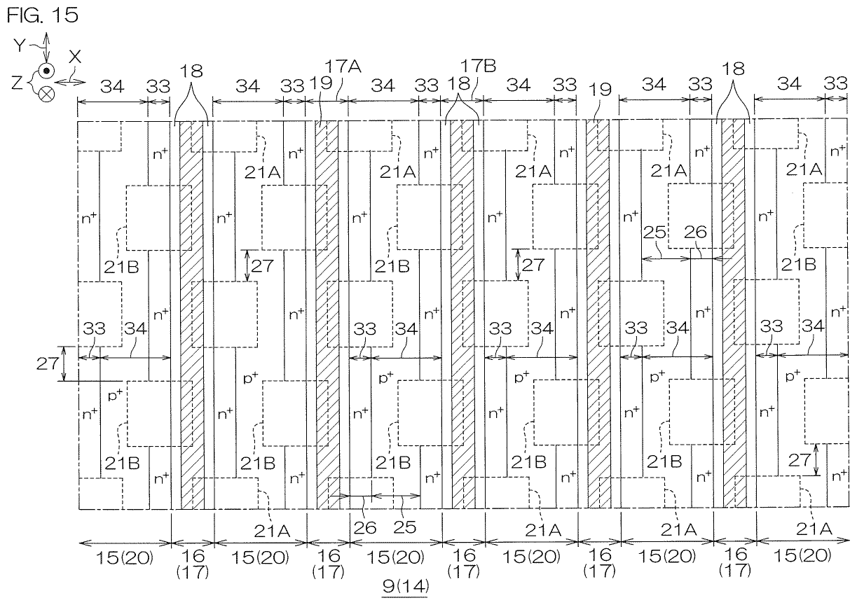

FIG. 15 to FIG. 22 are views showing first to sixth modification examples of the semiconductor device 1. Next, the modification examples of the semiconductor device 1 shall be described with reference to FIG. 15 to FIG. 22.

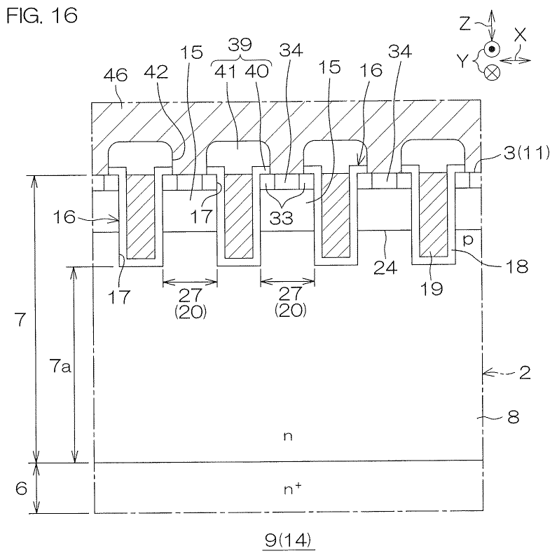

With reference to FIG. 15 and FIG. 16, in each first trench 17A or 17B, the plurality of first electric field relaxation structures 21A and the plurality of second electric field relaxation structures 21B are arranged at intervals along the second direction Y. In each mesa portion 20, the plurality of first electric field relaxation structures 21A of the first trench 17A and the plurality of second electric field relaxation structures 21B of the first trench 17B are thereby arranged at intervals along the second direction Y. In other words, the first electric field relaxation structures 21A of the first trench 17A do not overlap the second electric field relaxation structures 21B of the first trench 17B in the first direction X.

As a result, each mesa portion 20 includes a channel section 27 in which neither the first electric field relaxation structure 21A nor the second electric field relaxation structure 21B is formed. The channel section 27 is a region having a fixed width in the second direction Y. With reference to FIG. 16, in the channel section 27, the source regions 33 are formed on the side walls of the trenches 17 on both sides of the mesa portion 20 in the first direction X. In this embodiment, the contact region 34 (the first portion 25) is sandwiched between a pair of the source regions 33 in the first direction X.

In another aspect, in each mesa portion 20, the plurality of source regions 33 are arranged at intervals in the extension direction of the trench structure 16 on both of one side and the other side in the first direction X. Unlike the embodiment in FIG. 5, the source region 33 on one side and the source region 33 on the other side respectively have end portions in the channel section 27 and partially overlap each other in the first direction X. On the other hand, in the embodiment in FIG. 5, the source region 33 on one side and the source region 33 on the other side are formed such as not to overlap each other in the first direction X.

According to this arrangement, the channel section 27 is formed by aligning the plurality of first electric field relaxation structures 21A and the plurality of second electric field relaxation structures 21B at intervals along the second direction Y. In the channel section 27, channels can be formed along the side walls of the trench 17 on both sides of the mesa portion 20 in the first direction X. As a result, a channel density in each mesa portion 20 can be improved. That is, in the embodiments in FIG. 15 and FIG. 16, the concentration of electric fields on the insulating film 18 of the trench 17 can be relaxed effectively and the channel density can be improved.

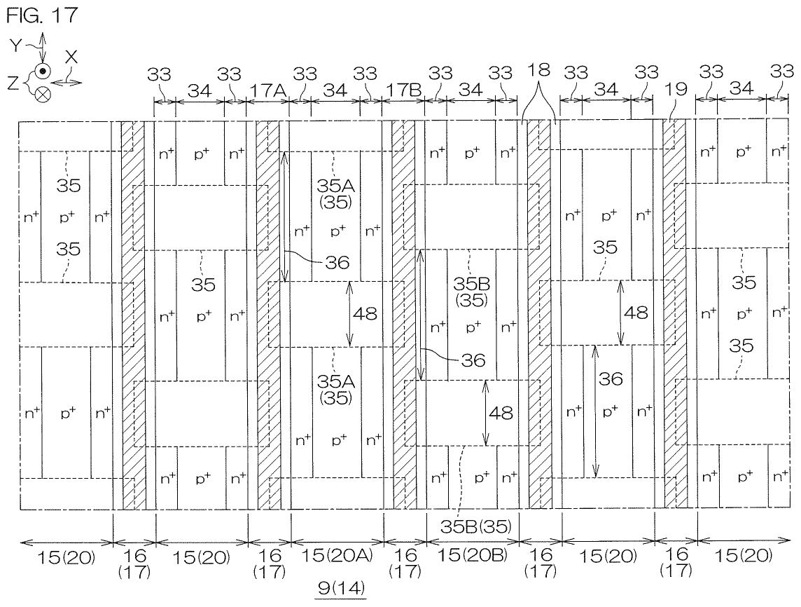

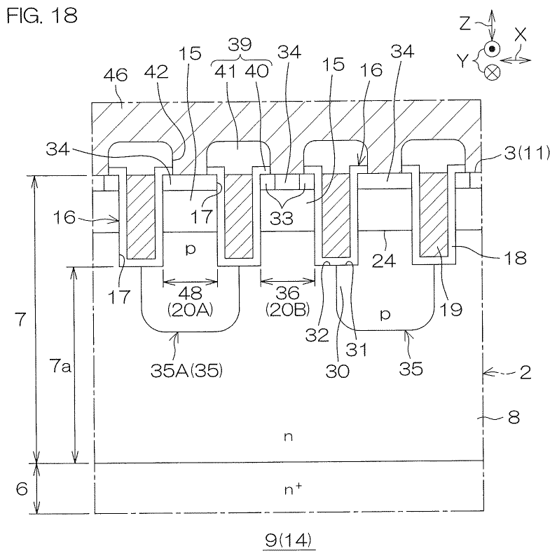

With reference to FIG. 17 and FIG. 18, the first electric field relaxation structure 21A of the first trench 17A and the second electric field relaxation structure 21B of the first trench 17B are integrated to form one electric field relaxation structure 35 that straddles the first trench 17A and the first trench 17B.

The electric field relaxation structures 35 are arranged in a staggered pattern in plan view. For example, the plurality of mesa portions 20 in the first direction X are defined as a first mesa portion 20A and a second mesa portion 20B which are alternately arranged. In the first mesa portion 20A, a plurality of electric field relaxation structures 35A (may be referred to as “first electric field relaxation structures”) are arranged at intervals in the extension direction of the trench structure 16. In the second mesa portion 20B, a plurality of electric field relaxation structures 35B (may be referred to as “second electric field relaxation structures”) are arranged at intervals in the extension direction of the trench structure 16. The plurality of electric field relaxation structures 35A and the plurality of electric field relaxation structures 35B are arranged such as not to overlap each other in the first direction X. The plurality of electric field relaxation structures 35A and the plurality of electric field relaxation structures 35B are thereby arranged in a staggered pattern as a whole.

In each mesa portion 20A or 20B, a region in which the plurality of electric field relaxation structures 35A and 35B are not formed is a channel section 36. The channel section 36 is a region having a fixed width in the second direction Y. On the other hand, in each mesa portion 20A or 20B, a region in which the plurality of electric field relaxation structures 35A and 35B are formed is a non-channel section 48. The non-channel section 48 is a region having a fixed width in the second direction Y. In each mesa portion 20A or 20B, the channel sections 36 and the non-channel section 48 are alternately arranged in the extension direction of the trench structure 16.

With reference to FIG. 18, in the channel section 36, the source regions 33 are formed on the side walls of the trenches 17 on both sides of each mesa portion 20A or 20B in the first direction X. In this embodiment, the contact region 34 (the first portion 25) is sandwiched between a pair of source regions 33 in the first direction X. On the other hand, in the non-channel section 48, the contact region 34 is formed over an entirety of the first principal surface 3 between the trench structure 16 on one side and the trench structure 16 on the other side of each mesa portion 20A or 20B. That is, in the non-channel section 48, the contact region 34 crosses the mesa portions 20A and 20B from the trench structure 16 on the one side to the trench structure 16 on the other side of each mesa portion 20A or 20B.

According to this arrangement, the electric field relaxation structures 35A and 35B are formed around the upper, lower, left, and right sides of the channel section 36 of sheet surface. As a result, since the electric field relaxation can be performed from the upper, lower, left, and right sides of each channel section 36, the relaxation effect of the concentration of electric fields on the insulating film 18 of the trench 17 can be improved.

Also, in each mesa portion 20A or 20B, the channel sections 36 and the non-channel sections 48 are alternately arranged along the extension direction of the trench structure 16 and are clearly demarcated. A function of the channel section 36 to form the current path and a function of the non-channel section 48 to secure electrical contact with the body region 15 can thereby be divided. As a result, ON-operation can be efficiently performed.

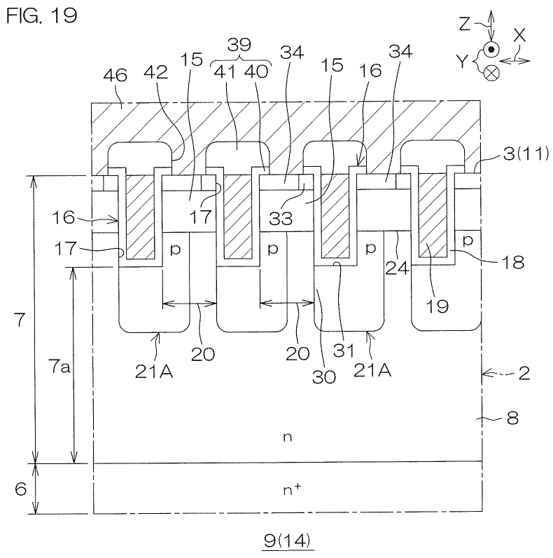

With reference to FIG. 19, each electric field relaxation structure 21A or 21B (just the electric field relaxation structure 21A in FIG. 19) may have the end portion 30 at a position of the wall surface (the side wall) of the trench 17 in the width direction of the trench 17. For example, in sectional view, the wall surface (the side wall) of the trench 17 and the end portions 30 of the electric field relaxation structures 21A and 21B may continue in a rectilinear shape in the vertical direction Z.

According to this arrangement, it is possible to further relax the concentration of electric fields on the bottom wall of the trench 17 since the bottom wall of the trench 17 is completely covered with the electric field relaxation structure 21A or 21B. However, as compared with structure in FIG. 6 to FIG. 9, the electric field relaxation structures 21A and 21B become obstacles and it becomes difficult to form a current path in a portion of the bottom wall of the trench 17. Therefore, in comparison with FIG. 6 to FIG. 9, there is a possibility that the on-resistance increases. In other words, in the structure in FIG. 6 to FIG. 9, the relaxation of the concentration of electric fields on the bottom wall of the trench 17 and reduction of the on-resistance can be achieved in a well-balanced manner.

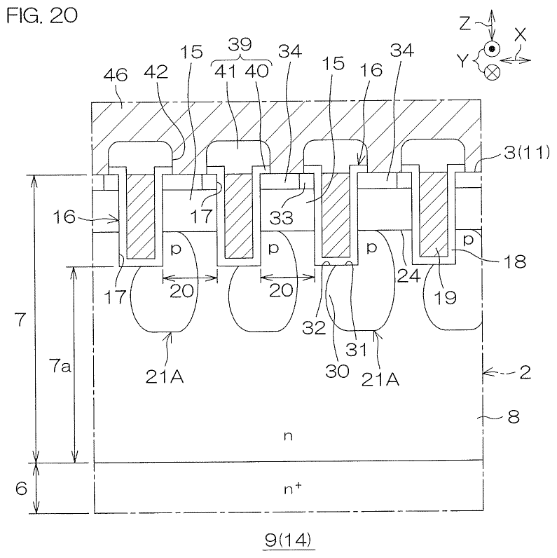

With reference to FIG. 20, the end portion 30 of each electric field relaxation structure 21A or 21B do not have a planar shape that is parallel or substantially parallel to the vertical direction Z from the bottom wall of the trench 17, and may have a curved surface shape bulging in the horizontal direction (at least one of the first direction X and the second direction Y).

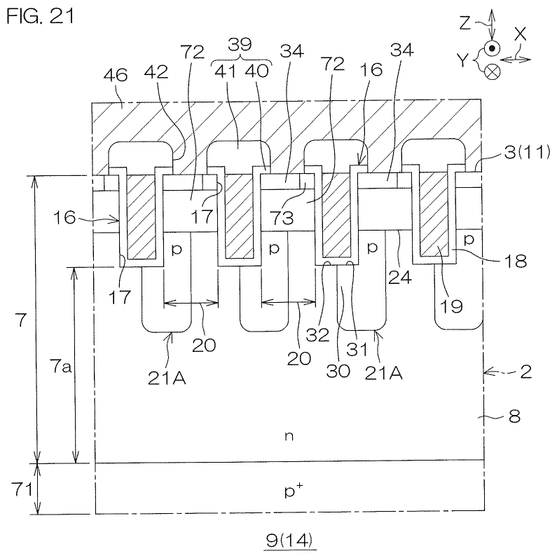

With reference to FIG. 21, an element structure of the semiconductor device 1 may be an IGBT (insulated gate bipolar transistor) structure different from the MISFET structure of FIG. 6 to FIG. 9. In this case, a collector region 71 of the p-type may be formed instead of the base layer 6. Also, a base region 72 of the p-type may be formed by the body region 15, and an emitter region 73 of the n-type may be formed by the source region 33.

Also in this arrangement, each channel portion 22 is sandwiched between the electric field relaxation structures 21A and 21B from both sides in each of the first direction X and the second direction Y and is surrounded by the electric field relaxation structures 21A and 21B. As a result, since electric field relaxation can be performed from the upper, lower, left, and right sides of each channel portion 22, the relaxation effect of the concentration of electric fields on the insulating film 18 of the trench 17 of the trench gate structure according to the IGBT can be improved.

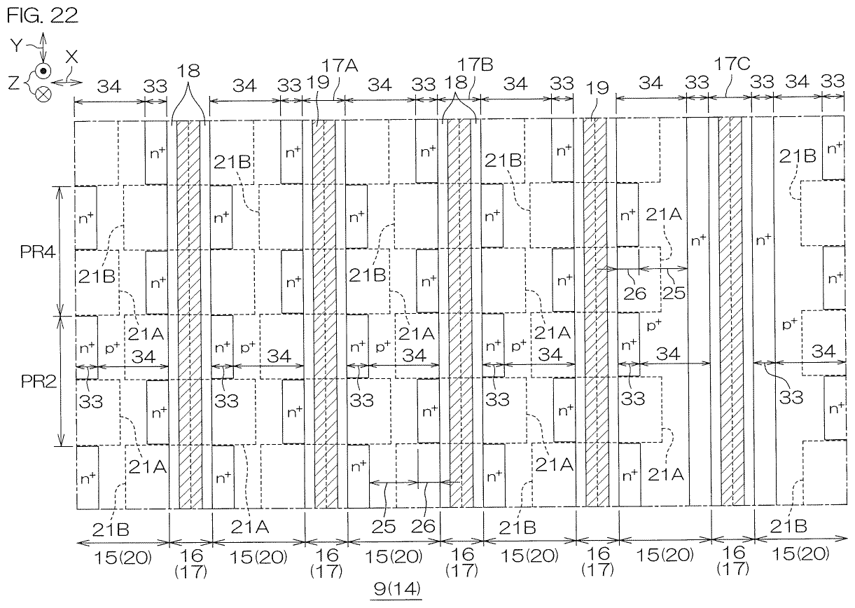

With reference to FIG. 22, the trench 17 may include second trenches 17C in which the electric field relaxation structures 21A and 21B are not formed. That is, the electric field relaxation structures 21A and 21B do not have to be formed in all of the plurality of trenches 17 that are formed in the chip 2 and the electric field relaxation structures 21A and 21B do not have to be formed in some of the trenches 17 (the second trenches 17C).

Although the preferred embodiment of the present disclosure has been described above, the present disclosure can be implemented in other modes.

For example, with each preferred embodiment described above, the base layer 6 and the semiconductor layer 7 that each include the SiC monocrystal are adopted. However, at least one or all of the base layer 6 and the semiconductor layer 7 may include a monocrystal of a wide bandgap semiconductor other than the SiC monocrystal.

The wide bandgap semiconductor is a semiconductor that has a greater bandgap than the bandgap of silicon. As examples of a monocrystal of a wide bandgap semiconductor, silicon carbide (SiC), gallium nitride (GaN), diamond (C), gallium oxide (Ga₂O₃), etc., can be cited. The base layer 6 and the semiconductor layer 7 may be constituted of monocrystals of the same type or may be constituted of monocrystals of different types. Also, at least one or all of the base layer 6 and the semiconductor layer 7 may be constituted of silicon (Si).

Hereinafter, examples of features extracted from this Description and the attached drawings shall be described. Hereinafter, the alphanumeric characters, etc., in parentheses represent the corresponding components, etc., in the preferred embodiment described above, but are not intended to limit the scope of each clause to the preferred embodiment. The “semiconductor device” in the following clauses may be replaced with an “SiC semiconductor device,” a “wide bandgap semiconductor device,” “a semiconductor switching device,” a “semiconductor rectifier,” a “MISFET device,” an “IGBT device,” a “diode device,” etc., as needed.

### CLAUSE 1-1

A semiconductor device (1) including:
a chip (2) that has a first principal surface (3) and a second principal surface (4) on an opposite side thereto;
a first impurity region (7) of a first conductivity type that is formed in a surface layer portion of the first principal surface (3);
a second impurity region (15, 72) of a second conductivity type that is formed in a surface layer portion of the first impurity region (7);
a third impurity region (33, 73) of the first conductivity type that is formed in a surface layer portion of the second impurity region (15, 72);
a plurality of trenches (17) that are arranged at intervals in a first direction (X), each trench (17) being formed such as to reach the first impurity region (7) through the third impurity region (33, 73) and the second impurity region (15, 72) from the first principal surface (3) and extending in a second direction (Y) intersecting the first direction (X);
a first electric field relaxation structure (21A) of the second conductivity type that is formed integrally with the second impurity region (15, 72) which is in contact with a first trench (17A, 17B) among the plurality of trenches (17), and that is formed on one side in the first direction (X) with respect to the first trench (17A, 17B); and
a second electric field relaxation structure (21B) of the second conductivity type that is formed integrally with the second impurity region (15, 72) which is in contact with the first trench (17A, 17B), and that is formed on the other side in the first direction (X) with respect to the first trench (17A, 17B), wherein
a plurality of the first electric field relaxation structures (21A) and a plurality of the second electric field relaxation structures (21B) are alternately arranged along the second direction (Y).

According to this arrangement, since the first electric field relaxation structure (21A) and the second electric field relaxation structure (21B) are formed on the bottom wall of the first trench (17A, 17B), it is possible to relax the concentration of electric fields on the bottom wall of the trench (17A, 17B). Also, a plurality of the first electric field relaxation structures (21A) and a plurality of the second electric field relaxation structures (21B) are alternately arranged along the second direction (Y). Since electric fields in regions adjacent to the first electric field relaxation structures (21A) and the second electric field relaxation structures (21B) can thereby be relaxed from the upper, lower, left, and right sides, the concentration of electric fields on the trench (17A, 17B) can be relaxed effectively.

### CLAUSE 1-2

The semiconductor device (1) according to Clause 1-1, wherein
a pair of the first trenches (17A, 17B) are mutually adjacent in the first direction (X), and
at a position adjacent to, in the first direction (X), a region between a plurality of the first electric field relaxation structures (21A) of the one first trench (17A) of the pair of first trenches (17A, 17B), the second electric field relaxation structure (21B) of the other first trench (17B) is arranged.

### CLAUSE 1-3

The semiconductor device (1) according to Clause 1-2, wherein the first electric field relaxation structure (21A) of the one first trench (17A) and the first electric field relaxation structure (21A) of the other first trench (17B) are arranged in rectilinear shapes along the first direction (X).

### CLAUSE 1-4

The semiconductor device (1) according to Clause 1-2 or 1-3, wherein in each first trench (17A, 17B), the plurality of first electric field relaxation structures (21A) and the plurality of second electric field relaxation structures (21B) are arranged without intervals along the second direction (Y).

According to this arrangement, it is possible to further improve the electric field relaxation effect since the plurality of first electric field relaxation structures (21A) and the plurality of second electric field relaxation structures (21B) can be densely arranged such as to be close to each other.

### CLAUSE 1-5

The semiconductor device (1) according to Clause 1-2 or 1-3, wherein in each first trench (17A, 17B), the plurality of first electric field relaxation structures (21A) and the plurality of second electric field relaxation structures (21B) are arranged at intervals along the second direction (Y).

According to this arrangement, it is possible to effectively relax the concentration of electric fields on the trench (17A, 17B) and improve the channel density.

### CLAUSE 1-6

The semiconductor device (1) according to Clause 1-1, wherein
a pair of the first trenches (17A, 17B) are mutually adjacent in the first direction (X), and
the first electric field relaxation structure (21A) of the one first trench (17A) of the pair of first trenches (17A, 17B) and the second electric field relaxation structure (21B) of the other first trench (17B) are integrated to form one electric field relaxation structure (35) that straddles the one first trench (17A) and the other first trench (17B).

### CLAUSE 1-7

The semiconductor device (1) according to any one of Clauses 1-1 to 1-6, wherein the second impurity region (15, 72) includes a channel portion (22) that is physically separated from the first electric field relaxation structure (21A) and the second electric field relaxation structure (21B), the channel portion (22) having a channel formed along the first trench (17A, 17B), and a non-channel portion (23) that is physically integral with the first electric field relaxation structure (21A) and the second electric field relaxation structure (21B) and has a bottom wall covered with the first electric field relaxation structure (21A) and the second electric field relaxation structure (21B).

A portion of the second impurity region (15, 72) which is physically integral with the first electric field relaxation structure (21A) and the second electric field relaxation structure (21B) is covered with a portion of the second conductivity type (the second impurity region (15, 72) and the first electric field relaxation structure (21A) and the second electric field relaxation structure (21B)) from the side wall to the bottom wall of the trench (17). Since a range in which an inversion layer is to be formed along an inner wall of the trench (17) becomes prolonged, a voltage (a threshold voltage) necessary for channel formation is likely to be selectively high in the corresponding portion. Thus, a variation in a threshold voltage can be reduced by forming, as the non-channel portion (23), the portion of the second impurity region (15, 72) which is physically integral with the first electric field relaxation structure (21A) and the second electric field relaxation structure (21B).

### CLAUSE 1-8

The semiconductor device (1) according to Clauses 1-7, wherein
the third impurity region (33, 73) is selectively formed in the channel portion (22), of the channel portion (22) and the non-channel portion (23), and
the semiconductor device (1) further includes a fourth impurity region (34) of the second conductivity type that is formed in the surface layer portion of the second impurity region (15, 72) and has an impurity concentration higher than the second impurity region (15, 72), and
the fourth impurity region (34) includes a contact region (34) that is formed in the non-channel portion (23).

### CLAUSE 1-9

The semiconductor device (1) according to any one of Clauses 1-1 to 1-8, wherein one or both of the first electric field relaxation structure (21A) and the second electric field relaxation structure (21B) has an end portion (30) at a central position in a width direction of the first trench (17A, 17B).

According to this arrangement, it is possible to sufficiently secure current path along the wall surface of the trench (17) since the first electric field relaxation structure (21A) and the second electric field relaxation structure (21B) are arranged at intervals between the wall surface of the trench (17). On-resistance can thereby be reduced.

### CLAUSE 1-10

The semiconductor device (1) according to Clause 1-9, wherein a bottom wall of the first trench (17A, 17B) includes a first portion (31) covered with one or both of the first electric field relaxation structure (21A) and the second electric field relaxation structure (21B) and a second portion (32) which is adjacent to the first portion (31) and covered with the first impurity region (7).

According to this arrangement, it is possible to sufficiently secure the current path along the wall surface of the trench (17) since a portion of the bottom wall of the trench (17) is covered with the first impurity region (7, 8) (the first conductivity type). On-resistance can thereby be reduced.

### CLAUSE 1-11

The semiconductor device (1) according to any one of Clauses 1-1 to 1-10, including:
a drain region (6) of the first conductivity type that is formed on the second principal surface (4) side with respect to the first impurity region (7);
a body region (15) that is formed by the second impurity region (15, 72);
a source region (33) that is formed by the third impurity region (33, 73); and
a trench gate structure (16) that is formed by the trench (17), an insulating film (18) covering the wall surface of the trench (17), and an embedded electrode (19) embedded in the trench (17).

According to this arrangement, it is possible to effectively relax the concentration of electric fields on the bottom wall of the trench gate structure (16) according to the MISFET (metal insulator semiconductor field effect transistor).

### CLAUSE 1-12

The semiconductor device (1) according to any one of Clauses 1-1 to 1-10, including:
a collector region (71) of the second conductivity type that is formed on the second principal surface (4) side with respect to the first impurity region (7);
a base region (72) that is formed by the second impurity region (15, 72); and
an emitter region (73) that is formed by the third impurity region (33, 73); and
a trench gate structure (19) that is formed by the trench (17), an insulating film (18) covering the wall surface of the trench (17), and an embedded electrode (19) embedded in the trench (17).

According to this arrangement, it is possible to effectively relax the concentration of electric fields on the bottom wall of the trench gate structure (16) according to the (IGBT) insulated gate bipolar transistor.

### CLAUSE 1-13

The semiconductor device (1) according to any one of Clauses 1-1 to 1-12, wherein the chip (2) includes an SiC chip (2).

### CLAUSE 1-14

The semiconductor device (1) according to any one of Clauses 1-1 to 1-13, wherein the first electric field relaxation structure (21A) and the second electric field relaxation structure (21B) have an impurity concentration higher than the second impurity region (15, 72).

### CLAUSE 1-15

The semiconductor device (1) according to Clause 1-14, wherein
the impurity concentration of the second impurity region (15, 72) is not less than 1×10¹⁵ cm⁻³ and not more than 1×10¹⁸ cm⁻³, and
the impurity concentration of the first electric field relaxation structure (21A) and the second electric field relaxation structure (21B) is not less than 1×10¹⁸ cm⁻³ and not more than 1×10²⁰ cm⁻³.

1. A semiconductor device comprising:
a chip that has a first principal surface and a second principal surface on an opposite side thereto;
a first impurity region of a first conductivity type that is formed in a surface layer portion of the first principal surface;
a second impurity region of a second conductivity type that is formed in a surface layer portion of the first impurity region;
a third impurity region of the first conductivity type that is formed in a surface layer portion of the second impurity region;
a plurality of trenches that are arranged at intervals in a first direction, each trench being formed such as to reach the first impurity region through the third impurity region and the second impurity region from the first principal surface and extending in a second direction intersecting the first direction;
a first electric field relaxation structure of the second conductivity type that is formed integrally with the second impurity region which is in contact with first trenches among the plurality of trenches, and that formed on one side in the first direction with respect to the first trenches; and
a second electric field relaxation structures of the second conductivity type that is formed integrally with the second impurity region which is in contact with the first trenches, and that is formed on the other side in the first direction with respect to the first trench, wherein
a plurality of the first electric field relaxation structures and a plurality of the second electric field relaxation structures are alternately arranged along the second direction.

2. The semiconductor device according to claim 1, wherein
a pair of the first trenches are mutually adjacent in the first direction, and
at a position adjacent to, in the first direction, a region between a plurality of the first electric field relaxation structures of the one first trench of the pair of first trenches, the second electric field relaxation structure of the other first trench is arranged.

3. The semiconductor device according to claim 2, wherein the first electric field relaxation structure of the one first trench and the first electric field relaxation structure of the other first trench are arranged in rectilinear shapes along the first direction.

4. The semiconductor device according to claim 2, wherein, in each first trench, the plurality of first electric field relaxation structures and the plurality of second electric field relaxation structures are arranged without intervals along the second direction.

5. The semiconductor device according to claim 2, wherein, in each first trench, the plurality of first electric field relaxation structures and the plurality of second electric field relaxation structures are arranged at intervals along the second direction.

6. The semiconductor device according to claim 1, wherein
a pair of the first trenches are mutually adjacent in the first direction, and
the first electric field relaxation structure of the one first trench of the pair of first trenches and the second electric field relaxation structure of the other first trench are integrated to form one electric field relaxation structure that straddles the one first trench and the other first trench.

7. The semiconductor device according to claim 1, wherein the second impurity region includes a channel portion that is physically separated from the first electric field relaxation structure and the second electric field relaxation structure, the channel portion having a channel formed along the first trench, and a non-channel portion that is physically integral with the first electric field relaxation structure and the second electric field relaxation structure and has a bottom wall covered with the first electric field relaxation structure and the second electric field relaxation structure.

8. The semiconductor device according to claim 7, wherein
the third impurity region is selectively formed in the channel portion, of the channel portion and the non-channel portion, and
the semiconductor device further comprises a fourth impurity region of the second conductivity type that is formed in the surface layer portion of the second impurity region and has an impurity concentration higher than the second impurity region, and
the fourth impurity region includes a contact region that is formed in the non-channel portion.

9. The semiconductor device according to claim 1, wherein one or both of the first electric field relaxation structure and the second electric field relaxation structure has an end portion at a central position in a width direction of the first trench.

10. The semiconductor device according to claim 9, wherein a bottom wall of the first trench includes a first portion covered with one or both of the first electric field relaxation structure and the second electric field relaxation structure and a second portion which is adjacent to the first portion and covered with the first impurity region.

11. The semiconductor device according to claim 1, comprising:
a drain region of the first conductivity type that is formed on the second principal surface side with respect to the first impurity region;
a body region that is formed by the second impurity region;
a source region that is formed by the third impurity region; and
a trench gate structure that is formed by the trench, an insulating film covering the wall surface of the trench, and an embedded electrode embedded in the trench.

12. The semiconductor device according to claim 1, comprising:
a collector region of the second conductivity type that is formed on the second principal surface side with respect to the first impurity region;
a base region that is formed by the second impurity region; and
an emitter region that is formed by the third impurity region; and
a trench gate structure that is formed by the trench, an insulating film covering the wall surface of the trench, and an embedded electrode embedded in the trench.

13. The semiconductor device according to claim 1, wherein the chip includes an SiC chip.

14. The semiconductor device according to claim 1, wherein the first electric field relaxation structure and the second electric field relaxation structure have an impurity concentration higher than the second impurity region.

15. The semiconductor device according to claim 14, wherein
the impurity concentration of the second impurity region is not less than 1×10¹⁵ cm⁻³ and not more than 1×10¹⁸ cm⁻³, and
the impurity concentration of the first electric field relaxation structure and the second electric field relaxation structure is not less than 1×10¹⁸ cm⁻³ and not more than 1×10²⁰ cm⁻³.
